(19) United States
(12) Patent Application Publication
(10) Pub. No.: US 2021/0217919 A1
(43) Pub. Date: Jul. 15, 2021

(54) EXCITONIC DEVICE AND OPERATING METHODS THEREOF

(71) Applicant: ECOLE POLYTECHNIQUE FEDERALE DE LAUSANNE (EPFL), Lausanne (CH)

(72) Inventors: Dmitrii UNUCHEK, Lausanne (CH); Alberto CIARROCCHI, Lausanne (CH); Ahmet AVSAR, Lausanne (CH); Andras KIS, Ecublens (CH)

(21) Appl. No.: 17/058,939

(22) PCT Filed: May 28, 2019
(86) PCT No.: PCT/IB2019/054413

§ 371 Date: Nov. 25, 2020

(30) Foreign Application Priority Data
May 28, 2018 (IB) PCT/IB2018/053779

(51) Int. Cl. H01L 31/112

(52) U.S. Cl. CPC H01L 31/112; B82Y 10/00

(57) ABSTRACT

The present disclosure concerns an excitonic device including at least one heterostructure comprising or consisting solely of a first two-dimensional material or layer and a second two-dimensional material or layer. The at least one heterostructure being configured to generate interlayer excitons at high temperature or room temperature.

### CROSS-REFERENCE TO RELATED APPLICATIONS

The present application claims priority to international patent application number PCT/IB2018/053779 filed on May 28, 2018, the entire contents thereof being herewith incorporated by reference.

### FIELD OF THE INVENTION

The present invention concerns an excitonic device. The present invention also concerns excitonic device operating methods. The present invention also concerns room-temperature or high temperature control of exciton flux in an excitonic device.

### BACKGROUND

Devices relying on the manipulation of excitons, bound pairs of electrons and holes, hold great promise for the efficient interconnection between optical data transmission and electrical processing systems. While exciton-based transistor actions were successfully demonstrated in bulk semiconductor-based coupled quantum wells¹⁻³, the low temperature required for their operation limits their promise for practical applications.

Solid-state devices utilize particles and their quantum numbers for their operation, with electronics being the ubiquitous example. The need to improve power efficiency of charge-based devices and circuits is motivating research into new paradigms that would rely on other degrees of freedom. Candidates so far include spintronics and photonics^{9,10}. Excitons, electrically neutral quasi-particles formed by bound electrons and holes, could also be manipulated in solid-state systems. The development of such excitonic devices has so far been hindered by the absence of a suitable system enabling room-temperature manipulation of excitons, strongly limiting the expansion of the field.

### SUMMARY OF THE INVENTION

The present disclosure addresses the above-mentioned limitations by providing an excitonic device comprising at least one heterostructure comprising a first two-dimensional material or layer and a second two-dimensional material or layer, the at least one heterostructure being configured to generate interlayer excitons at high temperature or room temperature.

According to an aspect of the present disclosure, the present disclosure also concerns an excitonic switch or transistor or coupling device including the excitonic device.

The present disclosure also provides excitonic device operating methods according to claims 25, 30, 33 and 39.

Other advantageous features can be found in the dependent claims.

Recent emergence of two-dimensional (2D) semiconductors with large exciton binding energies^{4,5} provides new prospects for the realization of excitonic devices and circuits operating at room temperature.

Although individual 2D materials have short exciton diffusion lengths, the Inventors anticipated that the spatial separation of electrons and holes in different layers in heterostructures could help overcome this basic challenge and enable room temperature operation or high temperature operation of mesoscopic devices.

In the present disclosure, the Inventors disclose exemplary room temperature excitonic devices comprising, for example, MoS₂/WSe₂ van der Waals heterostructures that for example demonstrate gate-controlled transistor actions.

Long-lived interlayer excitons together with the long diffusion constant in an encapsulation, for example a boron nitride-encapsulated stack, demonstrate excitons diffusing over a 5 μm distance. The ability to manipulate exciton dynamics is demonstrated. This can be done, for example, by creating electrically reconfigurable confining and repulsive potentials for an exciton cloud. These results make a strong case for the integration of 2D materials in future commercial excitonic devices.

The above and other objects, features and advantages of the present invention and the manner of realizing them will become more apparent, and the invention itself will best be understood from a study of the following description with reference to the attached drawings showing some preferred embodiments of the invention.

### A BRIEF DESCRIPTION OF THE SEVERAL VIEWS OF THE DRAWINGS

FIG. 1a shows interlayer excitons in an exemplary WSe₂/MoS₂ van der Waals (vdW) heterostructure where a Type-II band alignment in the WSe₂/MoS₂ heterostructure (HS) with intralayer (X₀) and interlayer (Xᵢ) excitons are shown.

FIG. 1b is a schematic depiction of the exemplary WSe₂/MoS₂ heterostructure. The interlayer exciton has a permanent out-of-plane dipole moment p allowing manipulation via an electric field.

FIG. 1c is an optical image of the exemplary device with shading highlighting the different materials.

FIGS. 1d and 1e are spatial maps of photoluminescence at 670 nm and 750 nm, corresponding to MoS₂ and WSe₂ intralayer excitonic resonances. Photoluminescence is quenched in the heterostructure area due to efficient charge transfer. Scale bar is 5 μm for every panel.

FIG. 1f is a schematic of an exemplary excitonic device of the present disclosure.

FIG. 2a shows an exemplary excitonic transistor operation at room temperature, the application of voltages to transparent (for example, graphene) electrodes (1-3) can engineer a potential landscape for the diffusion of excitons, controlling their flux through the device.

FIGS. 2b and 2c show a calculated energy variation (SE for the excitons in the ON (free diffusion) and OFF (potential barrier) states.

FIGS. 2d and 2e are corresponding images of the exciton emission. Dashed lines indicate positions of the different layers forming the heterostructure and the top gate 1. Scale bar is 5 μm.

FIG. 2f shows the gate dependence of the ON/OFF ratio when optically exciting 3 μm away from the emission centre.

FIGS. 3a and 3b show a biasing of the excitonic device and a calculated energy profile δE of the indirect exciton for the forward and backward bias cases.

FIG. 3c is an image showing exciton emission from the device when injecting at a distance dᵢ₋ₒ=5 μm from the emission area. The laser spot is represented by the red circle. Scale bar is 5 μm.

FIG. 3d shows normalized output intensity as a function of the distance between optical injection and emission points, for the forward and backward bias configurations. Exciton diffusion over a distance of 5.5 μm is achieved.

FIGS. 4a, 4b and 4c show an electrically reconfigurable energy landscape and a calculated energy profile δE of the indirect exciton for the cases of a potential well, free diffusion and a potential barrier. FIGS. 4d, 4e and 4f show images of exciton emission for the configurations shown in FIGS. 4a to 4c. Incident laser light (circle) is focused on top of gate 2. Dashed lines indicate positions of different layers forming the heterostructure and the (graphene) top gate 2. Scale bar is 5 μm.

FIGS. 4g to 4i show a cross-section of the intensity profile along the device channel, integrated over its width for the three configurations described above. The shaded overlay represents the profile of the excitation laser.

FIG. 5a shows interlayer excitons in the WSe₂/MoS₂ vdW heterostructure and a spatial map of photoluminescence at 785 nm corresponding to the HS interlayer PL emission maximum, as shown in the PL spectra in FIG. 5b. Efficient interlayer charge transfer process in the encapsulated heterostructure (for example, encapsulated in hBN) results in further quenching of PL emission from the HS area.

FIG. 5b shows PL spectra from the exemplary structure fabricated on SiO₂.

FIG. 6a shows spectra of excitonic device emission and a distribution of photoluminescence emission intensity from the device, in the absence of an electric field. White dashed lines represent edges of constituent crystals. Scale bar is 5 μm.

FIG. 6b is a detailed spectrum of the emission pattern, showing interlayer exciton peak and WSe₂ intralayer emission. The Inventors note that this low-energy peak cannot be related to localized excitons in WSe₂, since they are only observed at cryogenics temperatures.

FIG. 6c shows a full spectrum of the emission shown in FIG. 6a, also showing the emission from MoS₂ which is blocked by the filter in the CCD image. Black dashed box refers to the magnified range of energies, represented in FIG. 6b. Scale bar is 5 μm long.

FIG. 7a concerns the characterisation of an additional WSe₂/MoS₂ heterostructure and shows a shaded optical image of the fabricated stack or structure.

FIG. 7b is an Atomic force microscopy height profile image of the HS.

FIGS. 7c to 7d show spatial maps of photoluminescence intensity at 670 nm, 750 nm and 785 nm emission wavelengths, corresponding to MoS₂, WSe₂ intralayer and HS interlayer excitonic resonances. Photoluminescence is quenched in the HS area due to efficient charge transfer. White dashed lines represent edges of constituent crystals. Scale bar is 5 μm long for every panel.

FIG. 8a shows excitonic transistor input and output and a cross-sectional profile of the device emission intensity along the white dashed line represented in FIGS. 8b and 8c obtained for different gate voltages V_{g1} from 0 V to 16 V with intermediate values of 6, 8 and 10 V. The dashed line represents the intensity profile of the laser spot.

FIGS. 8b and 8c are CCD images of the exciton emission in the ON state and the focused laser spot. Length of the dashed line is 10 μm.

FIGS. 9a to 9f show switching of the excitonic transistor and CCD images of the exciton emission from the device obtained for different gate voltages V_{g1} from 0 to 10 V with a step of 2V.

FIGS. 10a and 10d show spectra of light emitted from the device in different states, where FIG. 10a shows intensity distribution of light emission from the excitonic transistor in OFF and ON states (left and right respectively) and corresponding spectra collected from the entire device is shown in FIG. 10b. FIG. 10c is an intensity distribution of light emission from the excitonic device in confinement and expulsion configurations (left and right respectively) and corresponding spectra collected from the entire device is shown in FIG. 10d.

FIGS. 11a to 11h show a schematic depiction of the control over light emission. FIGS. 11a and 11b show energy profile for electrons and holes located in MoS₂. FIGS. 11c and 11d show expected emission images in the single-particle assumption. FIGS. 11e and 11f show an energy profile of an interlayer exciton in the presence of an external electric field. FIGS. 11g and 11h corresponding experimental results. Scale bar is 5 μm. FIGS. 11a to 11d are schematic drawings based on the hypothesis that, following the fast interlayer charge transfer, photoexcited carriers move independently, rather than being bound in interlayer excitons. The diffusion of single electrons and holes is then subject to the type II band alignment between MoS₂ and WSe₂, which restricts the motion of electrons to MoS₂ and holes to WSe₂. This charge separation is very efficient, as indicated by the strong suppression of intralayer emission from the HS area (FIG. 1e, 1f). Once the separation occurs, it is not very likely that the charges can hop between the layers: the band difference between MoS₂ and WSe₂ is more than 200 meV, so thermal excitation of 25 meV will not be enough for electrons to jump back in WSe₂ and holes to MoS₂. Second is the local electrostatic potential defined by the gate. The application of V_{g2}<0 creates a confining energy profile for single holes and a repulsive one for single electrons, as in a, c. Holes would then be confined in the WSe₂ area under the gate while electrons would be pushed out to MoS₂ areas next to the gate, where they would recombine with charges already presented in the monolayer part, resulting in PL from single layer areas of MoS₂ next to the gate (provided there are enough holes in MoS₂ to start with). One would then have the emission pattern shown in FIG. 11c, assuming the presence of native holes in MoS₂. In their absence, one would only see one emission spot, coinciding with the excitation laser spot. Along the same lines, applying a positive gate voltage to the middle gate (V_{g2}>0), would result in the repulsive potential for holes in WSe₂ and attractive for electrons in MoS₂. Recombination would then occur for electrons in MoS₂ in regions under the gate and holes in WSe₂ in regions outside the gate, FIG. 11d. This is in contradiction with the experimental observations in FIGS. 11e to 11h. In the case of interlayer exciton transport we instead have only a single energy profile (FIG. 11e, 11g), and the application of a positive voltage on the middle gate results in the expulsion of interlayer excitons from the injection region (FIG. 11f, 11h).

FIG. 12a show excitonic transistor characterisation for different positions of the excitation laser spot and shows normalized emission intensity (transistor output) as a function of the distance between optical injection and emission point which is the same as in FIG. 3c, shown for the ON (V_{g1}=0 V) and OFF (V_{g1}=16 V) states.

FIG. 12b shows a transistor efficiency calculated as the ratio between output emission in the ON and OFF states for different input-output separation distances. Efficiency reaches a maximum when the laser spot is moved completely beyond the gate, so that the energy barrier stays between the input and the output and thus effectively modulates exciton diffusion.

FIG. 13a shows the Characterization of the device at low temperatures and shows normalized output intensity as a function of the distance between optical injection and emission points, obtained at room temperature and 4.7 K. No electric field is applied.

FIG. 13b shows emission images of the device in ON (top) and OFF (down) states when measured at 4.7 K, with input-output separation as long as dᵢ₋ₒ=5.1 μm. Such long distance transistor switching was not observed at room temperature for this sample.

FIGS. 14a to 14f show heterostructure fabrication and optical images take during different fabrication steps where FIG. 14a shows exfoliation of the bottom hBN (b-hBN); FIG. 14b shows transfer of monolayer MoS₂ flake; FIG. 14c shows transfer of a monolayer WSe₂ flake; FIG. 14d shows encapsulation with top hBN (t-hBN); FIG. 14e shows the transfer of pre-patterned few-layer graphene stripes (Gr); and FIG. 14f shows metallization of Au/Ti contacts. Optical image of FIG. 14e is shown in black and white for better visibility of the final structure. Scale bar is 10 μm for every picture.

FIG. 15a shows a variation of PL emission from MoS₂ due to the inhomogeneity of substrate and shows an image of the photoluminescence emission coming from the device in the repulsive configuration shown in FIG. 4f.

FIG. 15b shows μ-PL spectra from the areas marked with circles in FIG. 15a showing different peak widths as a result of local inhomogeneity in the heterostructure. The shaded grey area is the part of spectrum cut by the 700 nm long-pass-filter. As it can be clearly seen in the image, areas where MoS₂ PL shows a low-energy tail due to broadening become visible to the CCD (left side of the device), while the others appear dark (right side).

FIG. 16a shows a reference experiment and a Photoluminescence spectrum from monolayer WSe₂ at different back-gate voltage values. A significant modulation of the emission intensity is observed.

FIG. 16b shows photoluminescence spectrum from monolayer WSe₂ when using top- and back-gates in the dual-gated configuration for the voltage range used in the experiment presented in FIG. 2. No appreciable intensity modulation is observed. Both measurements are performed on the same WSe₂ flake with the same cw excitation at 647 nm with 200 μW incident power.

FIGS. 17a to 17d show image post-processing where FIG. 17a is an original CCD image of the exciton emission for the configuration shown in FIG. 3a. FIG. 17b shows the same image after background subtraction. The dashed square corresponds to the area of interest, shown as FIG. 3c. FIG. 17c is the original CCD image of the exciton emission for the configuration shown in FIG. 3b. FIG. 17d is the same image after background subtraction. Scale bar is 15 μm in all images.

FIG. 18 shows modelling of exciton diffusion and is a schematic depiction of exciton generation in the pumping area (x<0), and diffusion outside for x>0 represented by exciton concentration n(x). Constant pumping by the laser (top left area) is determined by the generation rate G. Together with the recombination rate R, they the establish exciton concentration n₀. Concentration gradient outside the pumping area generates exciton flux j_{diff} that drives diffusion and leads to the exponential decay of exciton concentration along the x axis.

FIGS. 19a to 19c concern a numerical simulation of the interlayer exciton in the external field. FIG. 19a shows a 2D cross-sectional map of electric field amplitude distribution calculated for the device in the “exciton confinement” configuration, with −10 V applied to central gate, and side gates grounded.

FIG. 19b shows a corresponding amplitude of the vertical electric field (top) and electrostatic potential (bottom) along the heterobilayer. FIG. 19c shows the energy shift experienced by an interlayer exciton and a single hole along the same cross-section. FIG. 19d shows a projection along the x axis of the confinement force experienced by the interlayer exciton due to the presence of the electric field. Arrows show the direction of the force.

FIG. 20a shows a schematic depiction of an excitonic device structure according to another embodiment.

FIG. 20b shows an optical image of the device of FIG. 20a. Scale bar is 10 μm.

FIG. 20c shows band alignment in a MoSe₂/WSe₂ heterobilayer (upper panel) and an artistic representation of an interlayer exciton with its dipole moment \vec{p} (lower panel).

FIG. 20d shows a PL spectrum from the heterostructure, showing emission from MoSe₂, WSe₂ and interlayer excitons. Insets show PL spectra from MoSe₂ and WSe₂ monolayers.

FIG. 20e shows detail of the PL spectrum from the heterobilayer B, with numerical fits for the emission peaks.

FIG. 20f is a schematic of the spin-conserving (IX₁) and spin-flipping (IX₂) transitions in the K valley for the Excitonic device structure of this embodiment and their coupling with circularly-polarized light. FIG. 21a shows electrical control of polarization and a μ-PL map of the difference between right- and left-circularly polarized (CP) emission intensities when the device is pumped with right-CP light: δ/_{RL}=I_{R}−I_{L} as a function of the gate voltage V_{TG} in single-gate configuration. The dashed lines serve as guides for the eye.

FIGS. 21b to 21d show details of device operation in dual-gating mode. Left panel: PL spectra for V_{TG}=+8 V, 0 V and −8 V. Right panel: spatial imaging of ΔI_{RL} in the corresponding gate configurations. The silicon back-gate is kept at V_{BG}=10·V_{TG} to reach higher doping densities and further enhance the effect. Scale bar is 5 μm.

FIG. 22 shows polarization switching action and a plot of the difference between right- and left-circularly polarized (CP) emission intensities when the device is pumped with right-CP light: ΔI_{RL}=I_{R}−I_{L} as a function of the gate voltage V_{TG}. The resulting polarization is obtained by integrating over the entire measured emission spectrum.

FIG. 23a shows a schematic of an excitonic device structure according to another embodiment of the present disclosure.

FIG. 23b shows an optical image of the device of FIG. 23a, highlighting the different materials. Scale bar is 10 μm.

FIG. 23c shows polarization-resolved micro-photoluminescence spectrum from the WSe₂/h-BN/MoSe₂ heterotrilayer (left) and the WSe₂/MoSe₂ heterobilayer (right) excited with right circularly polarized light.

FIG. 23d shows energy of interlayer exciton emission as a function of applied vertical electric field (E_{z}) when sweeping at constant doping Device A or Device B. Solid lines correspond to the linear Stark shift of the dipole with size of 0.9 nm (0.6 nm) extracted for heterotrilayer (heterobilayer).

FIG. 24a shows in the leftmost figure: CCD image of the focused laser spot in the corner of the heterostructure, represented by the dashed line, and in other figures: CCD images of the IX PL normalized emission intensity, acquired for different incident powers Pᵢₙ. Scale bar is 4 μm.

FIG. 24b shows (bottom curve) an extracted blueshift δε_{BS} dependence on the incident power. The solid curve is a power-law fit δε_{BS}˜Pᵢₙ^{0.7}. Top curve: full width at half maximum (FWHM) of the interlayer emission spectra at different incident powers resembles the power dependency of the blueshift. FIG. 24c shows normalized PL Intensity versus distance from the excitation point r extracted from a. The laser profile is shown by the first shaped area. The next shaded area shows diffusion of excitons in Device B at 200 μW incident power. Dashed line represents 1/e of the maximal emission intensity. FIG. 24d shows an extracted effective diffusion length l_{D}^{eff} (a distance from excitation spot where the emission intensity drops to 1/e of its initial value) as function of incident power Pᵢₙ. The dashed line shows the diffusion length extracted from the tails in FIG. 24c, fitted by the convolution of the Gaussian-like laser profile with modified Bessel function of the second kind K₀. Inset schematics demonstrate density-dependent diffusion driven by exciton-exciton repulsion.

FIGS. 25a and 25b show real-space CCD images of the emitted PL intensity corresponding to the ON and OFF configurations of the excitonic transistor. The simulated energy shift Δε for the interlayer excitons in the two cases is drawn as a overlay.

FIGS. 25c and 25d show real-space CCD images of the exciton cloud polarization ΔI=I_{σ}_{⁺}−I_{σ}_{^{−}} measured simultaneously with FIGS. 25a and 25b.

FIGS. 25e and 25f show intensity profiles of emitted intensity and polarization along a cutline in the middle of FIGS. 25a and 25b and 25c and 25d, highlighting the operation of the excitonic valley transistor. The dashed rectangle in all images corresponds to the gate area, where the vertical electric field is modulated. Scale bar is 2 μm.

FIGS. 26a to 26c show real-space CCD images of the exciton cloud polarization ΔI=I_{σ}_{⁺}−I_{σ}_{^{−}} corresponding to the configurations of anti-confinement, free diffusion and confinement, observed at 720 nm resonant excitation with incident power of Pᵢₙ=220 μW. The simulated energy shift Δε for the interlayer excitons in the various cases is drawn as a yellow overlay. The red overlay shows the intensity profile along the lateral direction in the middle of the image. As a reference for the eye, the profile in the V_{g}=−7 V state is replicated as a dashed line in the last two panels. PL intensity images are shown as insets.

FIGS. 26d to 26f show “Energy vs x” diagram of the emission energy as a function of the lateral coordinate x in the same configuration as FIGS. 25a to 25c. The overlay shows the spectra from the central region.

FIG. 26g shows peak emission energy in the gate area (solid line) and outside of it (dashed line) as a function of the applied electric field for 500 μW and 66 μW incident power. In dashed line, the linear stark effect extracted from FIG. 23.

FIG. 26h shows a ratio between the blueshift Δε(E) and the blueshift at zero electric field Δε(0).

FIG. 26i shows an interlayer exciton density as a function of the applied electric field extracted from the non-linear behaviour of the energy shift Δε for 500 μW and 66 μW incident power. The dashed rectangle in all images corresponds to the gate area, where the vertical electric field is modulated. Error bars represent the propagation of fitting uncertainty on the density. Scale bar is 2 μm.

Herein, identical reference numerals are used, where possible, to designate identical elements that are common to the Figures.

### DETAILED DESCRIPTION OF SEVERAL EMBODIMENTS

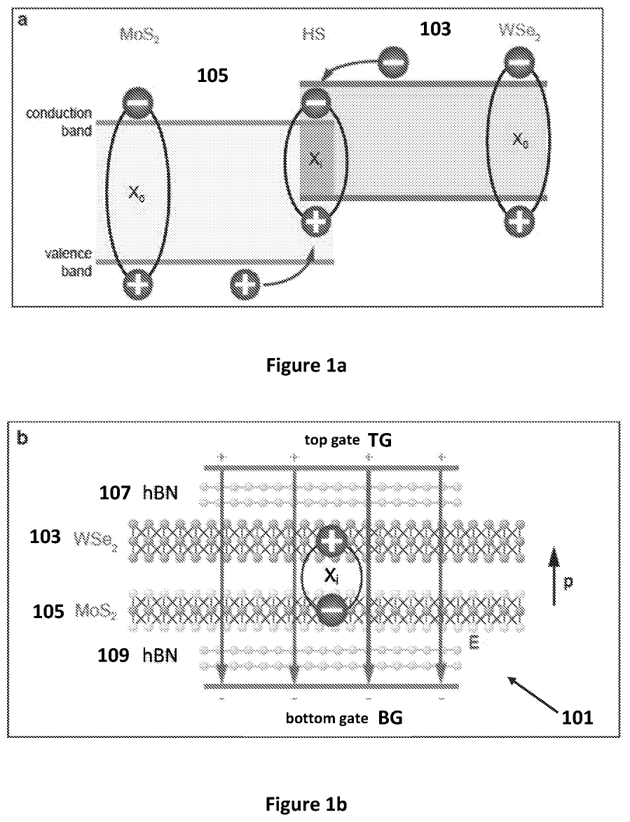

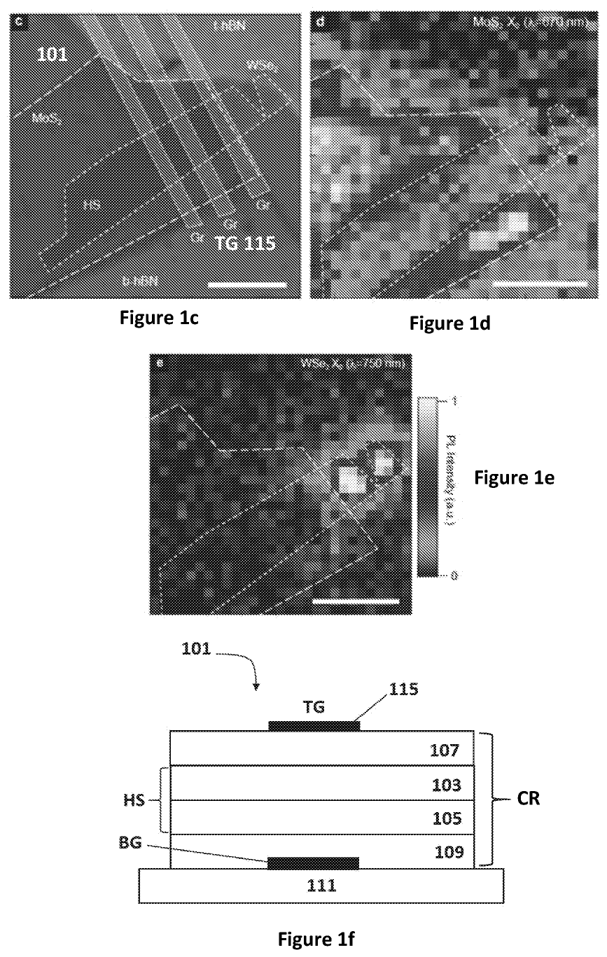

An exemplary excitonic device 100 of the present disclosure shown in FIG. 1f.

The excitonic device 101 includes at least one heterostructure HS comprising a first two-dimensional (2D) material or layer 103 and a second two-dimensional (2D) material or layer 105. The at least one heterostructure HS is configured to generate interlayer excitons at high temperature or at room temperature.

This temperature is, for example, the ambient temperature in which the excitonic device 101 is operating or to be operated or the temperature of the surrounding environment or area in which the device 101 is operating or to be operated.

In the context of the present disclosure, room temperature is defined, for example, as a temperature between 18° C. and 27° C., the range extremity values of 18° C. and 27° C. being included; or between 15° C. and 45° C. the range extremity values of 15° C. and 45° C. being included.

In the context of the present disclosure, high temperature is defined, for example, as a temperature between 18° C. and 27° C., the range extremity values of 18° C. and 27° C. being included; or between 15° C. and 45° C., the range extremity values of 15° C. and 45° C. being included; or between −100° C. and 27° C., the range extremity values of −100° C. and 27° C. being included; or between −100° C. and 45° C., the range extremity values of −100° C. and 45° C. being included.

The excitonic device 101 may include no cooling system or device and function without a cooling system or device. The excitonic device 101 may be a temperature cooling equipment-less device or cooling/refrigerator/heat pump-free device.

The excitonic device 101 may include one or more heterostructures HS. The heterostructure HS is a van der Waals heterostructure. The heterostructure HS comprises or consists solely of a layered combination of different 2D materials.

The first two-dimensional material or layer 103 and the second two-dimensional material or layer 105 consist of different two-dimensional materials or layers.

The first and second two-dimensional material or layer 103, 105 may comprise or consist solely of a transition metal dichalcogenide. The first and second two-dimensional material or layer 103, 105 may comprise or consist solely of a material of the type MX₂ where M is a transition metal atom and X a chalcogen atom. The first or second two-dimensional material or layer 103, 105 may comprise or consist solely of MoS₂, or MoSe₂, or WS₂, or WSe₂, or MoTe₂ or WTe₂ or ZrS₂, or ZrSe₂, or HfS₂, or HfSe₂. For example, the first two-dimensional material or layer 103 may comprise or consist solely of MoS₂ and the second two-dimensional material or layer 105 may comprise or consist solely of WSe₂ (or vice-versa).

The heterostructure HS may include a single layer, a few-layers (for example, two to five) of the first two-dimensional material 103 and/or a single layer or a few-layers (for example, two to five) of the second two-dimensional material 105.

The first two-dimensional material or layer 103 and the second two-dimensional material or layer 105 may be provided one on top of the other and may be directly in contact with each other. Alternatively, in another embodiment, the excitonic device 101 may include at least one inter-layer or inter-material located between the first two-dimensional material or layer 103 and the second two-dimensional material or layer 105. The least one inter-layer or inter-material is, for example, in direct contact with both the first two-dimensional material or layer 103 and the second two-dimensional material or layer 105. The at least one inter-layer or inter-material may comprise or consist solely of boron nitride or hexagonal boron nitride.

The heterostructure HS can have a type-II band alignment permitting charge separation between the constituent materials of the heterostructure HS. The type-II band alignment is the alignment type of the energy bands at the heterojunction or the interface of the first and second two-dimensional materials 103, 105 as shown for example in FIG. 1a. The band offset is a staggered gap (type II) band offset.

The type-II band alignment of the heterostructure HS restricts the motion of a first charge carrier to the first two-dimensional material or layer 103, and restricts the motion of a second charge carrier to the second two-dimensional material or layer 105, the first and second charge carriers being different charge carrier types (for example, electrons and holes).

The heterostructure HS is configured to generate interlayer excitons having a built-in interlayer electrical dipole moment p_{z} in an out-of-plane direction, as for example, shown in FIG. 1b.

The out-of-plane direction can be, for example a substantially vertical direction or direction substantially perpendicular to the plane defined by the heterostructure HS.

The Excitonic device 101 may further include encapsulation layers 107, 109 enclosing or sandwiching the at least one heterostructure HS, as for example shown in FIG. 1f. Each encapsulation layers 107, 109 is, for example, in direct contact with the heterostructure HS.

The encapsulation layer 107, 109 or both encapsulation layers 107, 109 can, for example, comprise or consist solely of boron nitride or hexagonal boron nitride. Alternatively, the encapsulation layer 107, 109 or both encapsulation layers 107, 109 can, for example, comprise or consist solely of MN, or a polymer layer, for example, PMMA (poly-methyl-metacrylate) or parylene or polyimide.

In an embodiment, the excitonic device 101 may include at least one central or active region CR consisting solely of the heterostructure HS (including or not including the inter-layer) sandwiched between encapsulation layers 107, 109.

The encapsulation layers 107, 109, the first and second two-dimensional materials or layers 103, 105, and the inter-layer may each comprise or consist solely of a single layer or a few-layers (for example, two to five).

The excitonic device 101 may further include a substrate 111 to which the heterostructure HS is attached. The substrate 111 may, for example, comprise or consist solely of Si and/or SiO₂.

The excitonic device 101 may further include at least one gate electrode 115 configured to apply an electric field to the heterostructure HS to control an exciton flux in the heterostructure HS. The gate electrode 115 can comprise or consist of a top gate electrode TG provided above the heterostructure HS and configured to apply an electric field perpendicular to a crystal plane or a plane of extension of the heterostructure HS or the first and second two-dimensional layers 103, 105.

A plurality of top gate electrodes TG or a series of interspaced of top gate electrodes TG may be included. The plurality of top gate electrodes TG or the series of interspaced of top gate electrodes TG are, for example, configured to apply an electric field to the heterostructure to create a laterally modulated electric field to drive exciton displacement or motion, for example motion towards regions of lower energy.

The excitonic device 101 may further include at least one or a plurality of bottom gate electrodes BG. Alternatively, the substrate may define or act as a bottom gate electrode. The gate electrode or electrodes may comprise or consist solely of graphene and/or a metal, for example, Cr, Pt or Pd.

The excitonic device 101 may also include or be combined with an interlayer exciton generation means or device 117. The interlayer exciton generation means or device 117 is configured to generate interlayer excitons in the heterostructure HS.

The present disclosure also concerns an excitonic switch or excitonic transistor including the excitonic device 101.

The present disclosure additionally concerns an excitonic coupling device for coupling an optical data transmission system and an electronic processing system, the excitonic coupling device including the excitonic device 101.

The excitonic device 101 and the different operation methods and applications thereof are now described and explained in more detail.

In this present disclosure, the inventors demonstrate the first room-temperature excitonic devices 101, based on atomically thin semiconductors that could open the way for wider application of excitonic devices in the industrial sector¹¹. Many applications can be envisaged, since excitons could be used to efficiently couple optical data transmission and electronic processing systems. While fast optical switches were already demonstrated^{12,13}, the comparably large size (˜10 μm)^{14,15} of such devices strongly limits packing density. This can be overcome in excitonic devices, whose characteristic size is that of electronic field-effect transistors (FETs).

Owing to their finite binding energy E_{b}, excitons can exist up to temperatures on the order of T˜E_{b}/k_{B}, where k_{B} is the Boltzmann constant. In a conventional III-V semiconductor coupled quantum well (CQW) with a size of a few nanometres, a relatively small binding energy around 10 meV allows exciton observation only at cryogenic temperatures (<100 K, ref. 3). To reach higher temperatures, different materials are required. Towards this, systems with higher E_{b} (in the range of tens of meV) have more recently been explored, such as (Al,Ga)N/GaN¹⁶ or ZnO¹⁷.

Two-dimensional semiconductors such as transition metal dichalcogenides (TMDCs) possess even larger exciton binding energies, which can exceed 500 meV in some cases due to strong quantum confinement^{4,5}. The Inventors exploit this material in the present disclosure for the realization of excitonic devices 101 operating at room temperature.

While intralayer excitons have relatively small lifetimes (τ˜10 ps)^{7,19}, the spatial separation of holes and electrons in interlayer excitons results in more than two orders of magnitude longer lifetimes, well in the nanosecond-range⁶.

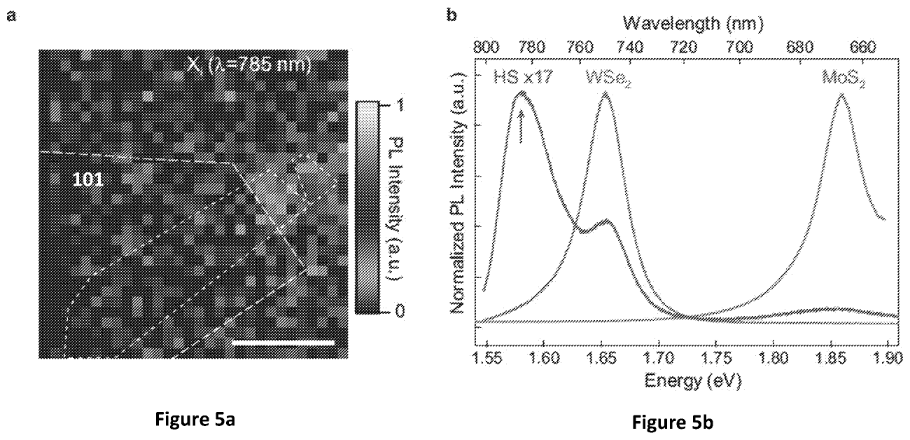

For the excitonic device 101 of the present disclosure, the Inventors take advantage of interlayer excitons hosted in an exemplary heterostructure HS that consists of an atomically thin MoS₂/WSe₂ heterostructure HS. Type-II band alignment^{20,21} (shown in FIG. 1a) results in charge separation between the constituent materials 103, 105, with electrons and holes residing in MoS₂ and WSe₂, respectively. The formation of indirect excitons is marked by the appearance of a new photoluminescence emission peak²², red-shifted by ˜75 meV with respect to the intralayer A exciton of the WSe₂ monolayer. FIG. 5b presents a typical PL spectrum obtained from such a heterostructure on SiO₂, were the spectral signature of the interlayer exciton is clearly visible, together with the individual WSe₂ and MoS₂ monolayers. Recent reports²³ suggest that excitons in the MoS₂/WSe₂ system are not only spatial-, but also momentum-indirect due to lattice mismatch. The phonon-assisted nature of the emission process further reduces the exciton recombination rate, yielding a longer lifetime^{8,24}. Such strongly extended lifetime is exploited by the Inventors to obtain interlayer exciton diffusion in the micrometre scale range, even at room temperature.

In order to obtain a pristine surface, the heterostructure HS is encapsulated in encapsulation layers 107, 109 for example hexagonal boron nitride (hBN) and annealed in high vacuum.

Multiple transparent top gates TG fabricated for example out of few-layer graphene can be included. A double-gate configuration allows to apply a vertical electric field without changing the carrier concentration in the MoS₂/WSe₂ heterostructure HS. FIG. 1c shows an optical micrograph of the resulting stack or structure.

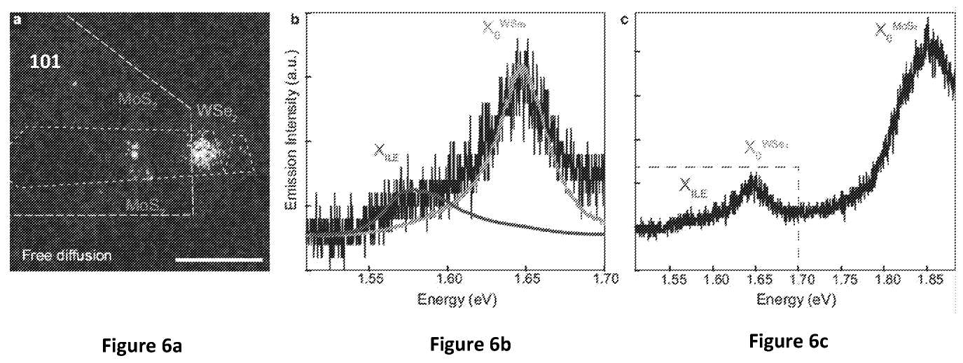

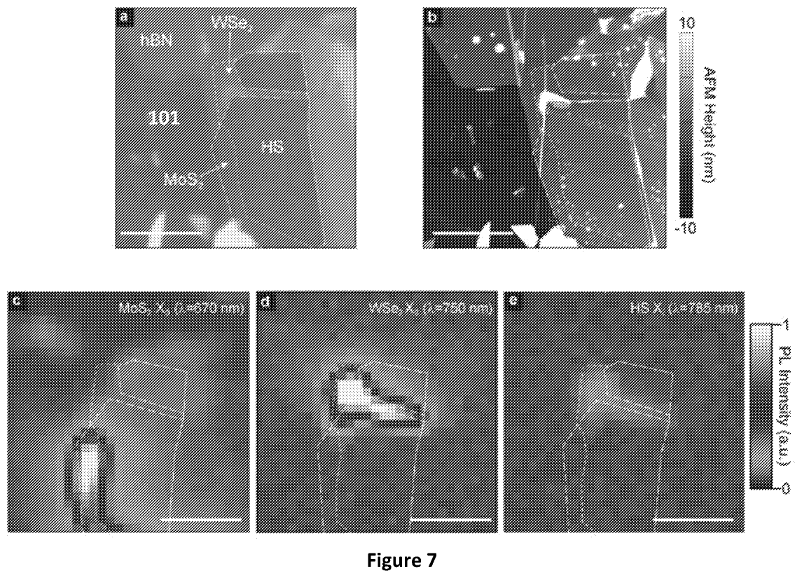

The structure is characterized by PL mapping at room temperature, under 647 nm-excitation. FIG. 1d, le and FIG. 5 show the intralayer emission distribution at the wavelengths characteristic of MoS₂ (650 nm), WSe₂ (760 nm) and the interlayer exciton (785 nm). While individual monolayers appear to be homogeneously bright, emission from the heterostructure region HS is uniformly quenched by more than three orders of magnitude due to the efficient charge transfer between layers²⁴. Even with such strong quenching, it was still possible to detect the interlayer peak in the PL spectra, (FIG. 6), confirming the generation of interlayer excitons. Since this effect is playing a central role, the Inventors fabricated three more heterostructures encapsulated in hBN, confirming the reproducibility of this result (see FIG. 7).

Given that excitons do not carry a net electric charge, one would not expect that their flow could be influenced by the direct application of an electric field. However, the confinement of oppositely charged carriers in different layers results in a well-defined interlayer exciton dipole moment p_{z} with an out-of-plane direction (FIG. 1b). An electric field perpendicular to the crystal plane can then be used to shift the exciton energy by δE=−p_{z}E_{z}, while a laterally modulated electric field E_{z}(x,y) will create an energy landscape, driving the exciton motion towards regions of lower energy. Exciton dynamics in the longitudinal direction can be modelled by a diffusion equation with an external potential (discussed in more detail later):

$$D \frac{{\partial }^{2} n}{\partial {x}^{2}} - \frac{D}{{k}_{B} T} \frac{\partial }{\partial x} ( \frac{\partial φ}{\partial x} n ) + G - \frac{n}{τ} = \frac{\partial n}{\partial t} \qquad eq . 1$$

where n, D, p and τ are the interlayer exciton concentration, diffusion coefficient, dipole moment and lifetime; φ is the exciton potential (including φₑₗ=p_{z}E_{z}) and G is the optical generation rate. This simple model qualitatively shows how the application of an electrical field E_{z} can affect interlayer exciton diffusion, as will be discussed later.

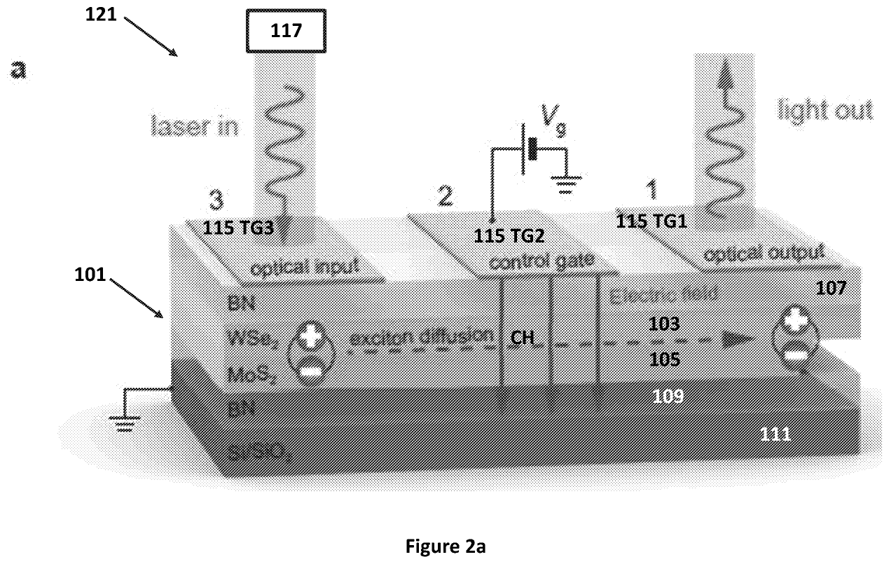

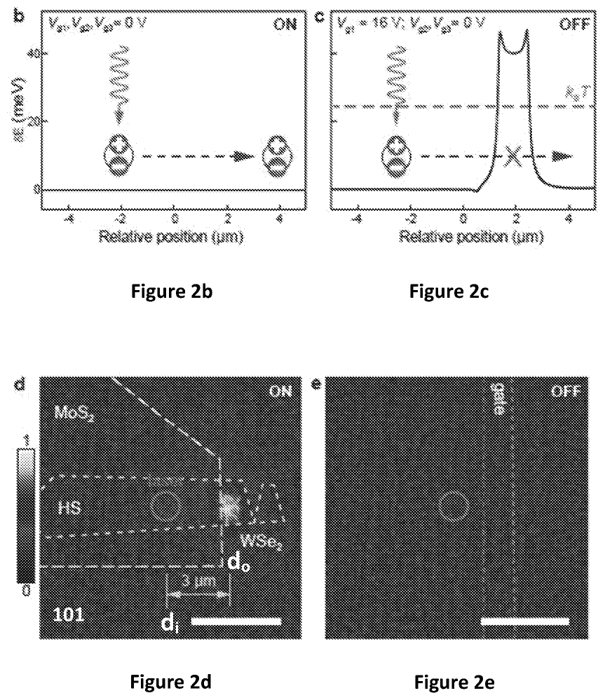

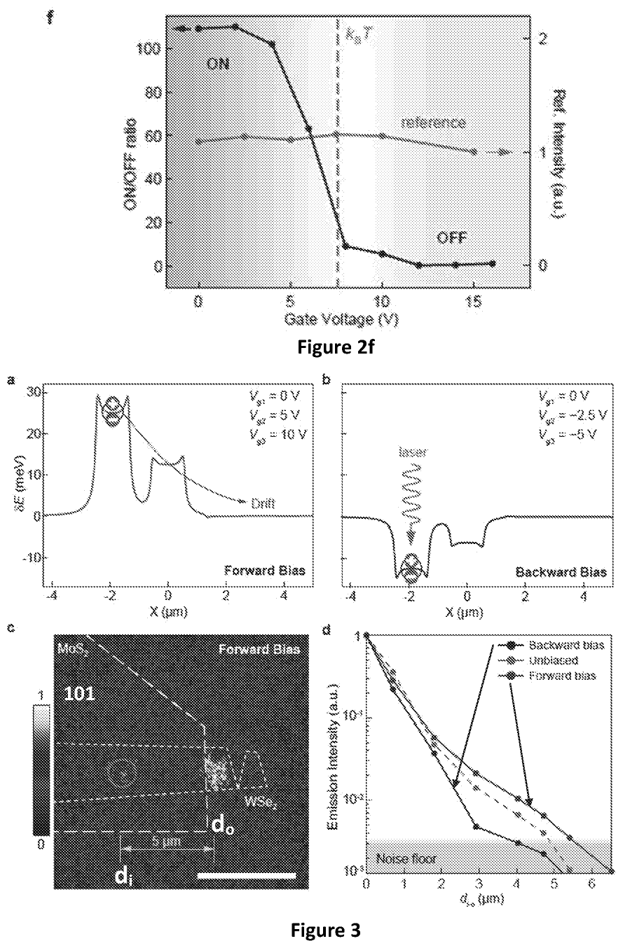

An embodiment of the present disclosure concerns an electrically controlled excitonic switch or excitonic transistor 121, represented schematically in FIG. 2a. The excitonic switch 121 includes the excitonic device 101. The first and second two-dimensional materials or layers 103, 105 of the heterostructure HS used in this exemplary embodiment are MoS₂ and WSe₂.

An interlayer exciton generation means or device 117 comprising or consisting of a laser provides energy to generate carriers and interlayer excitons in the heterostructure HS.

Alternatively, the interlayer exciton generation means device 117 may comprise or consist of a current or carrier injector configured to generate carriers in the heterostructure HS that subsequently form interlayer excitons in the heterostructure HS. The excitonic device 101 may include the current or carrier injector. The current or carrier injector may be integrated into the excitonic device.

Laser light focused inside the heterostructure area (input) generates interlayer excitons, which diffuse along a channel CH of the heterostructure HS.

The channel CH is defined in the heterostructure HS by the first and second two-dimensional materials or layers 103, 105. The generated interlayer excitons are guided or displaced through the channel CH.

However, the low brightness of interlayer emission makes monitoring the device operation challenging. For this reason and to facilitate monitoring of the interlayer excitons, the Inventors use an exposed WSe₂ extending out of the heterostructure HS (or having a longer planar extension than the MoS₂ layer) as a bright emitter. This feature is only necessary for investigation and confirmation of the generated interlayer excitons and does not necessarily need to be present in a device. Here, interlayer excitons diffuse towards the edge of the heterostructure HS. During this diffusion process, interlayer excitons are expected to dissociate into single carriers, which are allowed to diffuse inside the first and second two-dimensional materials or layers 103, 105 that in the present case are monolayer MoS₂²⁵ and WSe₂²⁶, where they experience recombination with native charges, resulting in bright emission.

The emitted radiation is recorded simultaneously using a CCD camera and a spectrometer (further details provided below) to have both spatial and spectral emission profiles. This allows to further confirm the presence and diffusion of interlayer excitons inside the heterobilayer HS (FIG. 6). In the absence of applied fields (FIG. 2b), excitons diffuse away from the pumping area (circle in FIG. 2d) due to temperature and concentration gradients²⁷, and reach the recombination site, approximately 3 μm away.

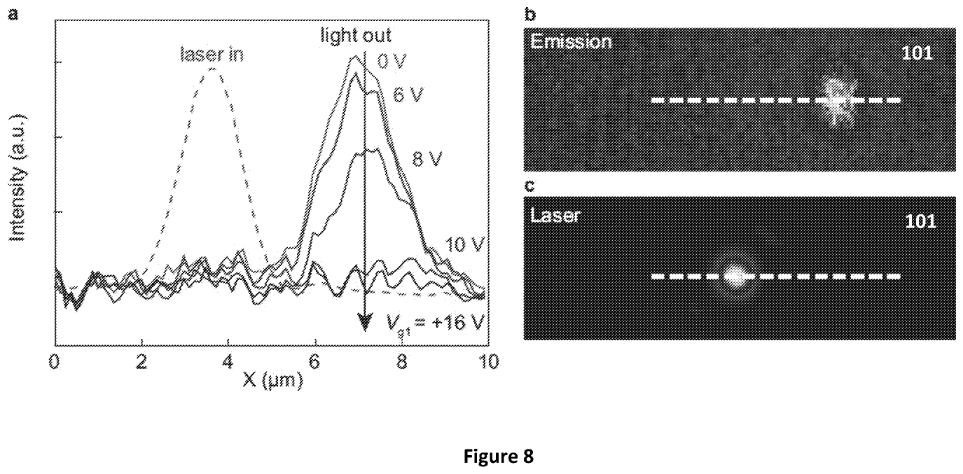

Comparison of pumping/emission profiles (FIG. 8) lets us exclude the possibility of a direct excitation of monolayer WSe₂ by the low-intensity tail of the laser spot. This situation (bright output) is shown in the emission image in FIG. 2d, and corresponds to the ON state of the excitonic transistor.

On the contrary, by introducing a potential barrier higher than k_{B}T on the path of the diffusing excitons (FIG. 2c), one impedes their motion, resulting in the suppression of light emission (FIG. 2e). This can be achieved, for example, using only one top electrode TG located along and/or above the exciton diffusion path or channel CH and to which a voltage is applied while grounding the device, for example, via substrate 111. Alternatively, a bottom gate BG of the device can be grounded. While three top gate electrodes TG1, TG2, TG3 are shown in FIG. 2a, the device may include fewer top gates, for example, only one top gate. In this way, one can achieve efficient electrical modulation or control of the output emission, as shown in FIG. 2f, where the emission intensity (normalized by the value in the OFF state, corresponding to V_{g1}=+16 V) is plotted as a function of applied voltage. As reference, we also plot the intensity modulation (similarly normalized by the value at V_{g1}=+16 V) observed when the laser beam is located on the emission centre (dᵢ₋ₒ=0 μm). The switching threshold is around 8 V, which corresponds well with the calculated exciton energy modulation of δE˜k_{B}T˜25 meV (dashed line).

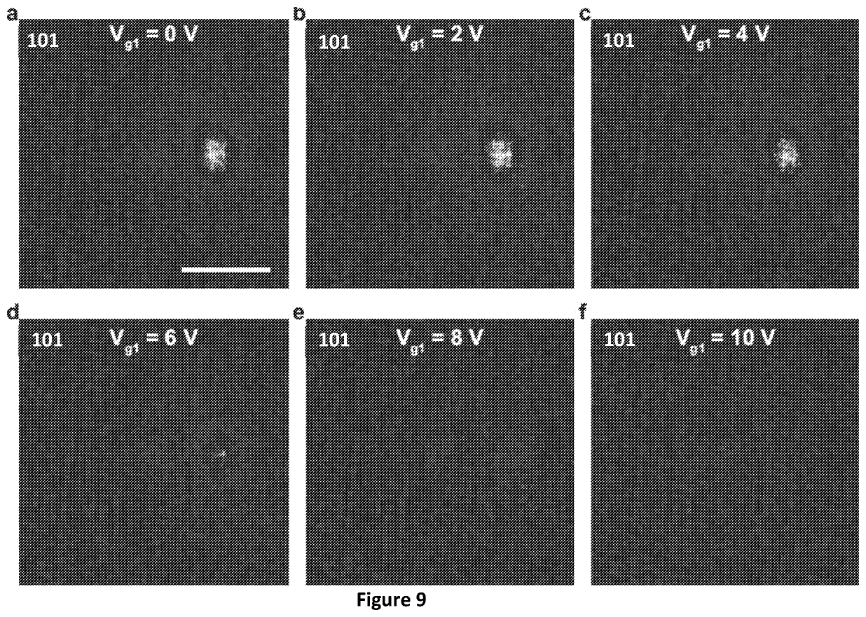

This result is consistent with our model: since the energy barrier height starts to become comparable to thermal excitation, it is now possible to block the diffusion of exciton flux. An intensity ON/OFF ratio larger than 100 is obtained, limited by the noise level of the setup in the OFF state (see also FIGS. 8 and 9). This is the first reported excitonic transistor 121 with a complete suppression of emission in the OFF state.

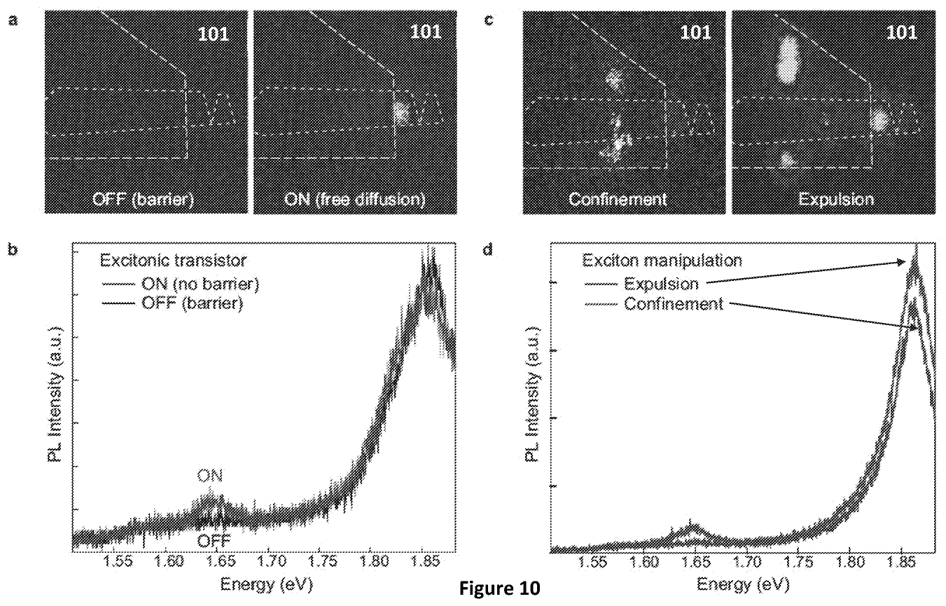

This effect is also clearly visible in the spectrum of the emitted light, where the WSe₂ peak is selectively suppressed when the device is in the OFF state (FIG. 10). It is also worth noting that strong emission from MoS₂ is detected in both states, as excitons can freely diffuse in other directions.

This aspect of the present disclosure thus further provides, for example, an excitonic switching method. In the excitonic device 101, interlayer excitons are generated in the heterostructure HS, and the generated interlayer excitons can be displaced along the heterostructure HS. Switching can be performed through the creation of the above-mentioned potential barrier by applying an electric field through heterostructure HS to impede or block the interlayer exciton displacement.

The potential barrier may be reduced or removed by reducing or removing the electric field through the least one heterostructure (HS) permitting interlayer exciton displacement.

This allows manipulation and control of the interlayer excitons or exciton cloud.

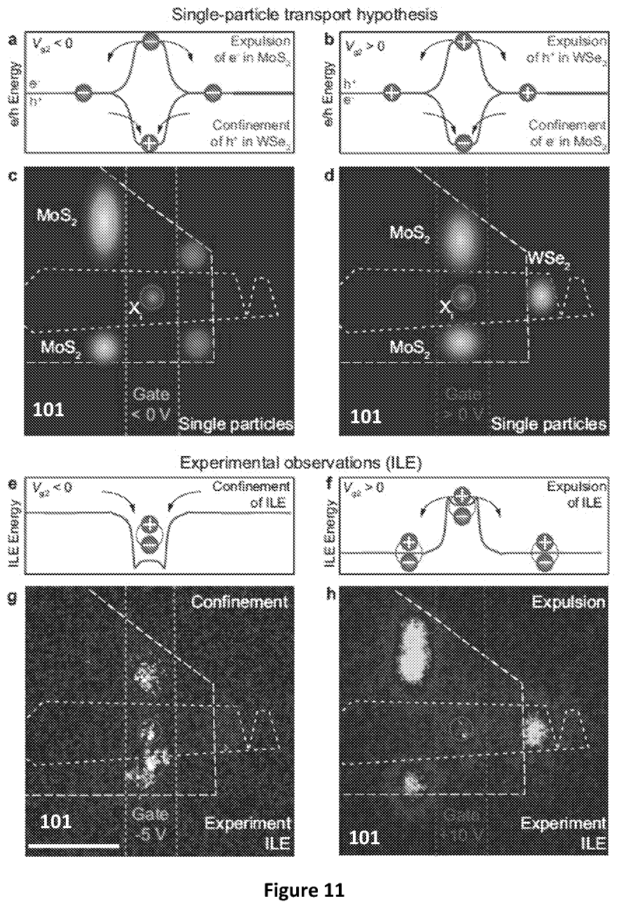

An alternative mechanism, which could in principle explain the recombination far away from the excitation spot, is based on the diffusion of single carriers rather than interlayer excitons. Indeed, it has been shown that such carriers (holes in particular) can have long lifetimes^{6,28,29}. However, experimental observations indicate that this is not the dominant mechanism in the heterostructure HS of the present disclosure. Firstly, The Inventors directly observe the production of interlayer excitons in the excitation area, even if the intensity is low. Secondly, for a flux of single carriers, the voltage modulation necessary to counteract thermal excitation and block the single-particle flux would be ˜50 mV, more than two orders of magnitude lower that the ˜8 V gate voltage required in the experimental result shown in FIG. 2. Finally, this mechanism would also result in different emission profiles for regimes of device operation which will be presented later (see FIG. 11).

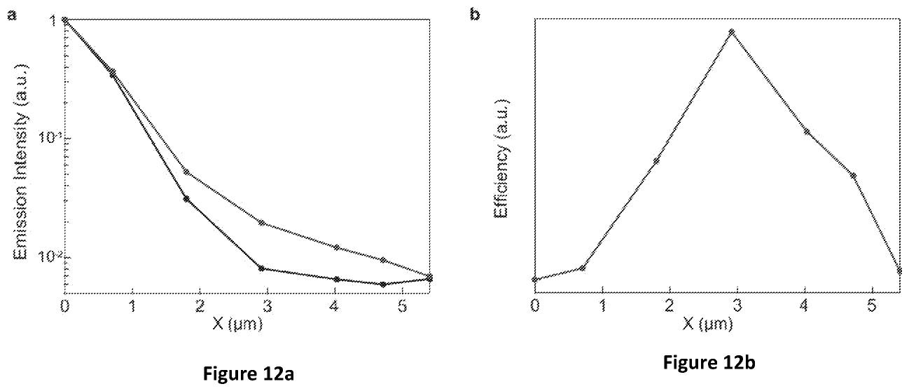

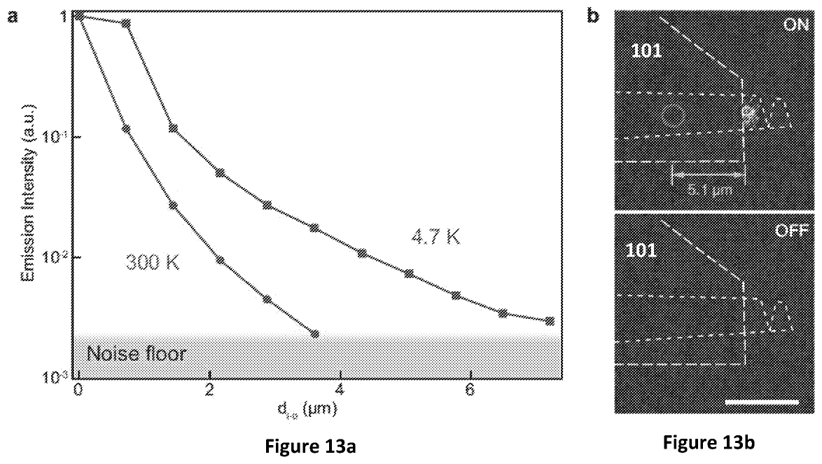

In order to exclude that the observed effect arises from an unwanted modulation of the charge carrier density in the first two-dimensional material or layer 103 that in the present example is WSe₂, the Inventors performed a calibration experiment where the excitation light is focused on the output area (input-output distance dᵢ₋ₒ=0) and the device is biased as before. This reference experiment is discussed in detail later, and the result of the experiment is presented in FIG. 2f (centre curve), showing that only a comparably small modulation of WSe₂ emission intensity is observed. This confirms the energy barrier to be at the origin of the switching behaviour. The Inventors further study the dependence of the on-off ratio on dᵢ₋ₒ (FIG. 12) by keeping the voltage profile constant and optically injecting excitons at different distances from the output point. Consistently with the model of the Inventors, efficient modulation is observed when the laser is focused beyond the formed energy barrier, with emission intensity decreasing with increasing dᵢ₋ₒ due to long-distance diffusion. The Inventors would like to note that the diffusion length can even be enhanced two-fold at lower temperature (4.7 K), resulting in operation over an even longer distance (FIG. 13).

Having demonstrated that one can block or allow spontaneous exciton diffusion, it is further possible in a further embodiment to creating a drift field in a desired direction, in analogy with the source-drain bias of a conventional FET.

This type of operation is shown for example in FIG. 3a, using a plurality of top gate electrodes, in this example three electrodes, and all three electrodes are used to create a potential ladder or lift going upwards/downwards with respect to the excitation point (FIG. 3a, b) depending on the amplitude and polarity of the voltage applied to each electrode.

The electrodes are used to define a plurality of electric fields in different spatial locations along the interlayer exciton diffusion path or channel CH. The upwards or downwards direction of the ladder or lift is defined by the electric field direction defined by the voltage polarity applied to the electrode. This allows the excitons to be manipulated or controlled and displaced across and through the device 101.

When excitons encounter a gradually decreasing energy profile (forward bias), their diffusion is enhanced by a drift term, allowing one to operate the device with a larger distance between optical input and output. As shown in FIG. 3c, this regime of electrically assisted diffusion can result in exciton transport over a 5 μm distance.

In order to have a more quantitative estimation of the induced modulation, the Inventors measured the dependence of the emission intensity on the distance from the laser spot as it is displaced away from the output area at fixed gate voltages. The results are represented in FIG. 3d, showing that the length over which excitons diffuse can be effectively modulated from 5.5 μm to 3 μm, with respect to ˜4 μm in the unbiased case. The modulation of the effective diffusion length with the potential φₑₗ qualitatively follows the model introduced in eq. 1 above.

The above aspect of the present disclosure thus provides, for example, an excitonic device operating method or switching method. Interlayer excitons can be generated in the heterostructure HS. One or more potential ladders or a potential gradient are created for manipulating the interlayer excitons. This is done by applying one or more different electric fields through the least one heterostructure HS, the electric fields being applied at different spatial portions across the heterostructure HS to create a drift electric field. The drift field displaces the excitons in an interlayer exciton displacement direction through the heterostructure HS.

The excitonic device 101 includes a plurality of electrodes configured to generate a plurality of spatially separated electric fields through the heterostructure HS. The spatially separated electric fields are spatially separated along a plane of the excitonic device 101.

One or more of the steps of the previously described method may also be included in this method to manipulate the interlayer excitons. For example, a potential barrier can be created by applying an electric field through heterostructure HS to impede or block the interlayer exciton displacement.

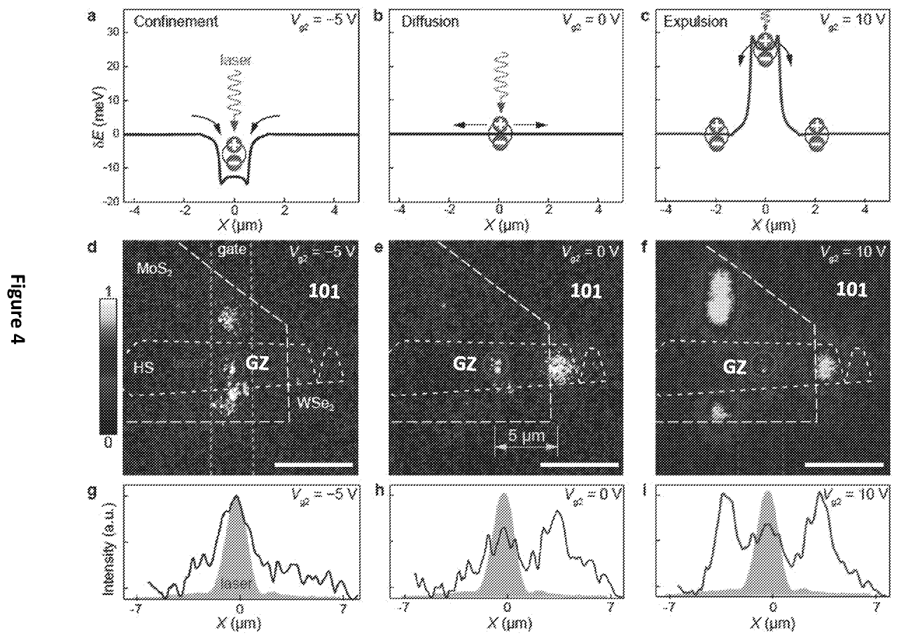

In another embodiment, the inventors further employ the multi-gate configuration to demonstrate more complex and electrically reconfigurable types of potential landscapes and related device operation. In FIG. 4a-c the calculated energy profiles for free diffusion (FIG. 3b) compared with a potential well (FIG. 4a) and a repulsive barrier (FIG. 4c) produced by the central gate 2 (TG2) is presented, while side gates (1 and 3) TG1, TG3 are kept grounded. In this case, the position of the optical pump is centred on the middle electrode TG2, corresponding to the centre of the well/barrier. Interlayer excitons are generated at a generation zone GZ indicated by the circle in FIG. 4d.

FIG. 4d and FIG. 4g show the CCD camera image and related emitted intensity profile along the device channel for the case of the potential well. One observes PL emission only from the narrow area below the central contact TG2 (shown by dashed rectangle), thus achieving electrical confinement of the excitonic cloud.

Conversely, when applying a positive voltage to create a “potential hill” (FIG. 4f, i), one sees an expulsion of excitons from the pumping area with the appearance of bright emission spots outside the middle section TG2 of the device, due to excitons drifting along the energy profile and recombining on the edges of the heterostructure HS. This is evident from a comparison with the free-diffusion case in FIG. 4e, h. Interestingly, one also observes higher-energy emission from the neighbouring MoS₂ monolayer parts inside the well in the case of exciton confinement. A similar effect is also observed during exciton expulsion, with bright spots appearing at the edges of the heterostructure HS around the repulsive potential.

Further inspection of the emission spectra from FIGS. 4d and f confirms this, showing decreasing (increasing) intensity of monolayer peaks when confining (anti-confining) the excitons (see FIG. 10). As discussed further below, the observed MoS₂ emission is affected by the local inhomogeneity of the substrate and by the optical filters used. As discussed earlier, the diffusion of single particles and their recombination with native charges available in the monolayers could play a role in light emission that extends from edges of the heterobilayer into the monolayers.

This aspect of the present disclosure thus provides, for example, an excitonic device operating method for confining an interlayer exciton cloud. Interlayer excitons are generated in a generation zone GZ of the heterostructure HS and a potential well is also created at or in the vicinity of the generation zone GZ by applying an electric field at the generation zone GZ. This permits to achieve electrical confinement of the interlayer excitons. Alternatively or additionally, a repulsive barrier can be created at the generation zone GZ by applying an electric field in an opposite direction at to expulse the interlayer excitons from the generation zone GZ.

The created potential well confines the interlayer excitons to form a bound exciton cloud. Removal of the created potential well allows displacement of the exciton cloud.

One or more of the steps of the previously above described methods may also be included in this method to manipulate the interlayer excitons. For example, a potential barrier can be created by applying an electric field through heterostructure HS to impede or block the interlayer exciton displacement. Alternatively or additionally, an electric field can be applied to displace the exciton cloud along the heterostructure (HS) to a predetermined location along the device, where, for example, light emission occurs via exciton dissociation or carrier recombination.

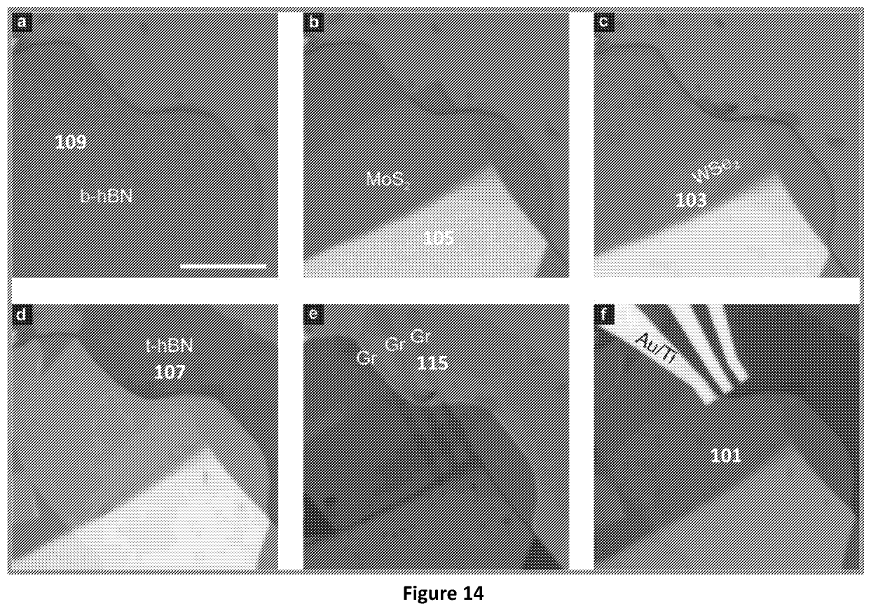

The exemplary heterostructure HS used in the above measured results was fabricated using polymer-assisted transfer (see FIG. 14) of monolayer flakes of hBN, WSe₂ (HQ Graphene) and MoS₂ (SPI). Flakes were first exfoliated on a polymer double layer, as in ref 30. Once monolayers were optically identified, the bottom layer was dissolved with a solvent and free-floating films with flakes were obtained. These were transferred using a setup with micromanipulators to carefully align flakes on top of each other. During the transfer process, the sharp edges of the flakes were aligned, in order to obtain a twist angle between the two crystal axes close to 0 (or 60) degrees. However, in the case of MoS₂/WSe₂ heterobilayers, the alignment has been shown not to be critical for the observation of interlayer excitons^{23,31}. This is due to the indirect (in reciprocal space) nature of the transition, as well as to the considerable lattice mismatch between the two layers (˜4%). Polymer residue was removed with a hot acetone bath. Once completed, the stack or structure was thermally annealed in high vacuum at 10⁻⁶ mbar for 6 h. Few-layer graphene flakes were obtained by exfoliation from graphite (NGS) on Si/SiO₂ substrates and patterned in the desired shape by e-beam lithography and oxygen plasma etching. After thermal annealing, the patterned flakes were transferred on top of the vdW stack using a polymer-assisted transfer and the entire structure was annealed again in high vacuum. Finally, electrical contacts were fabricated by e-beam lithography and metallization (60/2 nm Au/Ti).

All measurements presented in the work were performed in vacuum at room temperature if not specified otherwise. Excitons were optically pumped by a continuous wave (cw) 647 nm laser diode focused to the diffraction limit with a beam size of about 1 μm. The incident power was 250 μW. Spectral and spatial characteristic of the device emission were analysed simultaneously. The emitted light was acquired using a spectrometer (Andor), and the laser line was removed with a long pass 650 nm edge filter. For spatial imaging, a long-pass 700 nm edge filter was used so that the laser light and most of MoS₂ emission was blocked. Filtered light was acquired by a CCD camera (Andor Ixon). The room-temperature PL spectrum of MoS₂ shown in FIG. 5b was obtained under 150 μW excitation at 647 nm, while monolayer WSe₂ and the heterostructure fabricated on SiO₂ substrate were characterized under the 488 nm excitation.

Due to the small separation between the interlayer and the intralayer WSe₂ exciton peaks, it is not possible to completely distinguish them in the images acquired on the CCD. In fact, the tail of the WSe₂ monolayer peak normally has a considerable overlap with the spectral line of the interlayer exciton, meaning that weak luminescence around 785 nm can be observed even on monolayer WSe₂ (FIG. 6e), which is not due to interlayer excitons.

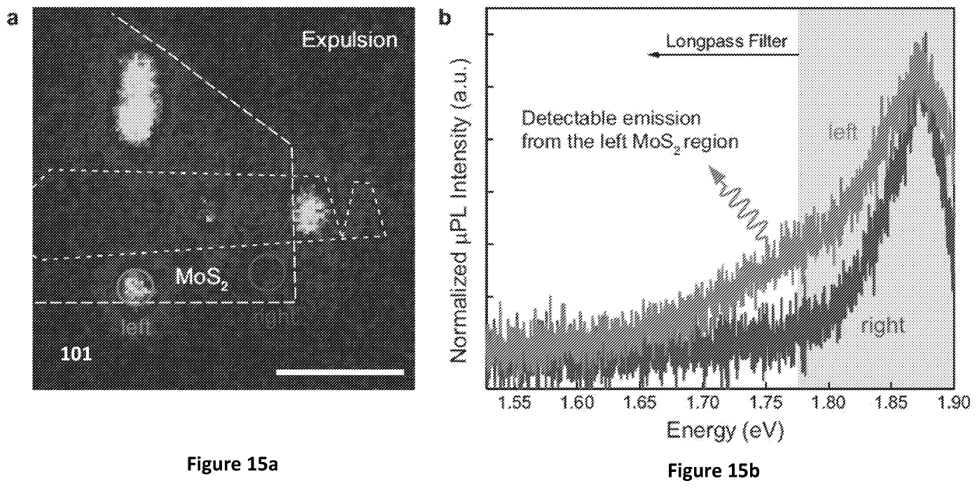

Because of the use of the 700 nm filter, the emission from monolayer MoS₂ is in principle not observable on the CCD. However, some light can be transmitted when the broadening of the PL peak results in a low-energy tail (see FIG. 15) extending beyond 700 nm. Local inhomogeneity in the substrate can affect this broadening, which could explain why the observed MoS₂ luminescence in FIG. 4f comes mostly from the left part of the device.

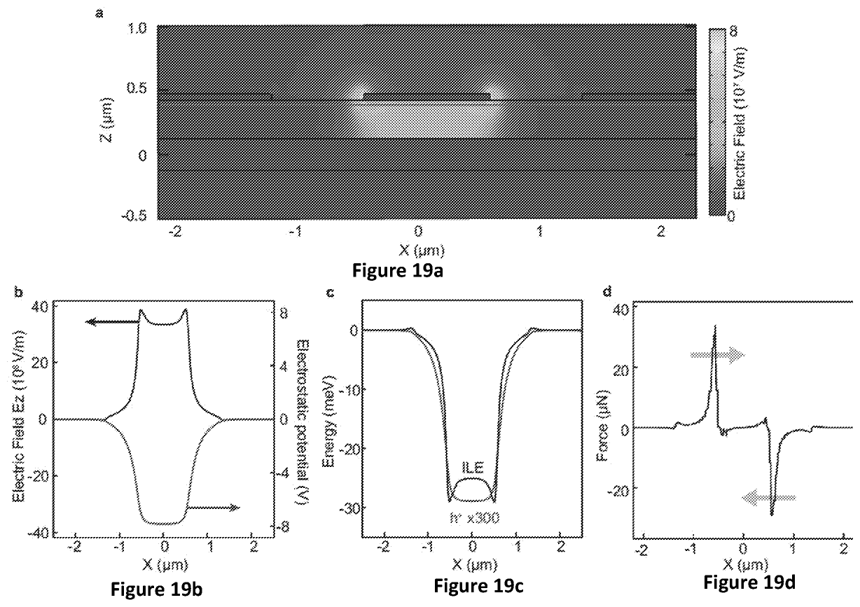

Low temperature measurements (FIG. 19) were performed in a liquid-He, continuous-flow cryostat (Oxford Instruments).

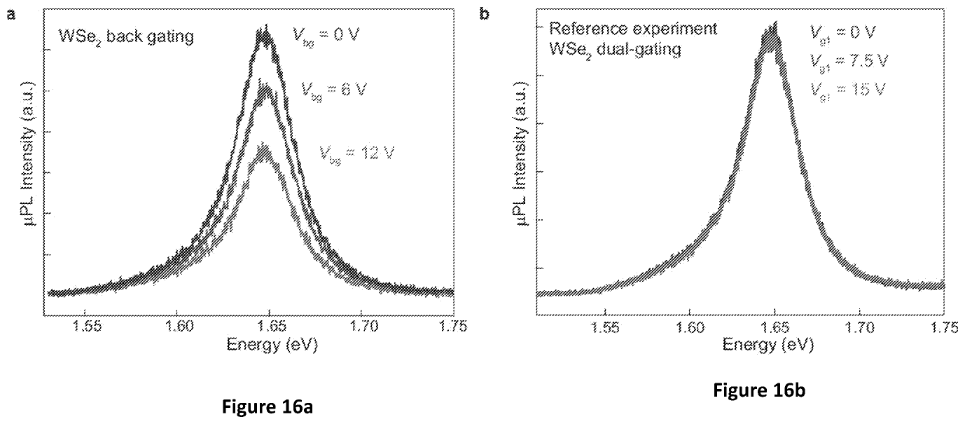

A reference experiment was performed in order to exclude spurious effects which could compromise a correct interpretation of the data. First, it was observed how the PL emission from monolayer WSe₂ changes when gating the device using the backgate. For this purpose, the Inventors excite with the laser beam directly the exposed WSe₂, and record the photoluminescence spectra obtained. As shown in FIG. 16a, when applying voltage to the backgate a modulation in the emission intensity it is clearly observable. Then, we repeat the same measurement but this time, instead of applying a voltage between the flake and the backgate BG, the Inventors bias the top- and back-gate, thus generating a vertical electric field inside the device. As shown in FIG. 16b, in this case one cannot observe a significant change in the emission intensity. This allows to rule out that the switching action observed could be due to a suppression of PL from a changing doping level in the material.

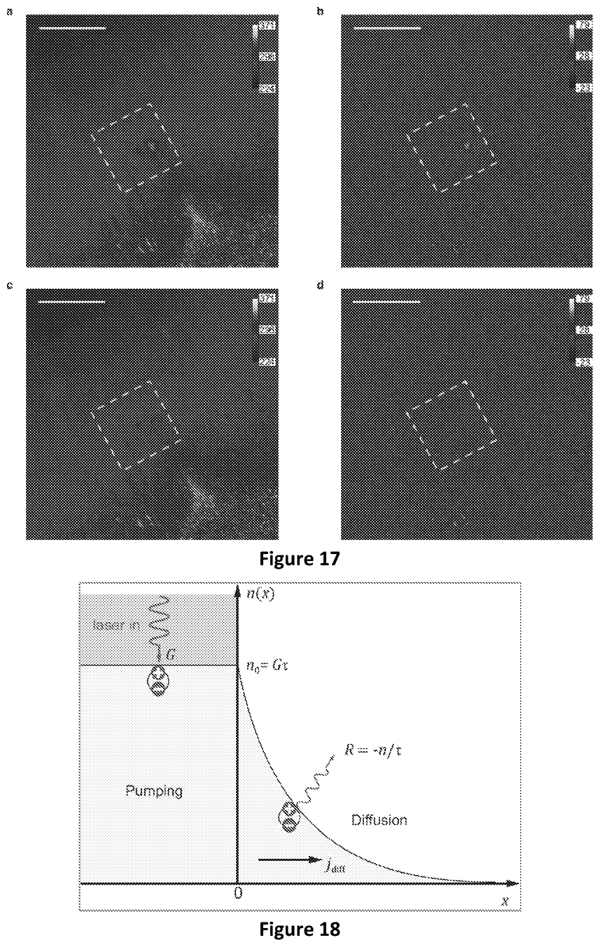

In order to aid the interpretation of images from the CCD camera, the Inventors have performed several image processing steps using ImageJ³². The Inventors first subtract from the original image a background image obtained without laser illumination, to account for ambient light noise. In some cases, a simple background is not sufficient for compensating the presence of spurious signals from unwanted reflections or changing ambient background. In these cases, a background image is generated by applying the rolling-ball algorithm implemented in the software. Contrast is adjusted to cover the range of values in the image. An example of the procedure is given in FIG. 17.

Dynamics of the exciton in the channel CH of the device can modelled with one-dimensional diffusion in the presence of an external potential φ(x) (temperature, electrostatic potential, dipole-dipole interaction). The gradient of exciton concentration n(x) drives diffusion current j_{diff} while the potential gradient causes drift j_{drift} as:

$${j}_{diff} = - D \frac{\partial n}{\partial x} {j}_{drift} = μ \frac{\partial φ}{\partial x} n$$

where μ is exciton mobility related to the diffusion coefficient D and the thermal energy k_{B}T by the Einstein relation D=μk_{B}T. We also include exciton generation rate G by means of optical pumping, and exciton recombination rate R, which is related to the exciton lifetime as R=−n/τ. From the exciton flux conservation equation we then obtain:

$$D \frac{{\partial }^{2} n}{\partial {x}^{2}} - \frac{D}{{k}_{B} T} \frac{\partial }{\partial x} ( \frac{\partial φ}{\partial x} n ) + G - \frac{n}{τ} = \frac{\partial n}{\partial t}$$

In the system, where excitons have a built-in vertical dipole moment p_{z}, the electrostatic potential induced by the vertical electric field is φₑₗ=E_{z}p_{z}. Since we use cw excitation, we assume a steady-state case (∂n/∂t=0). Considering φₑₗ as the main contribution to exciton drift, we obtain:

$$D \frac{{\partial }^{2} n}{\partial {x}^{2}} - \frac{Dp}{{k}_{B} T} \frac{\partial }{\partial x} ( \frac{\partial {E}_{z}}{\partial x} n ) + G - \frac{n}{τ} = 0$$

The model is further simplified by assuming two fundamentally different regions, shown in FIG. 18. First region is under constant homogeneous excitation so that concentration reaches an equilibrium value with equal recombination and generation rates, R=G. This equilibrium concentration is then n₀=Gτ.

Outside of the pumping region, excitons diffuse away driven by the concentration and potential gradients:

$$D \frac{{\partial }^{2} n}{\partial {x}^{2}} - \frac{Dp}{{k}_{B} T} \frac{\partial }{\partial x} ( \frac{\partial {E}_{z}}{\partial x} n ) - \frac{n}{τ} = 0$$

The case of diffusion in the absence of an external field can be solved analytically, revealing exponential decay of exciton density from the pumping region with a characteristic distance corresponding to the diffusion length l_{diff}=\sqrt{Dτ}.

n_{free}(x)=n₀e^{-x/l}^{_{diff}}

An applied non-homogeneous vertical electric field can alter the diffusion length (as demonstrated experimentally), which can be modelled as a change in the effective diffusion length.

Concerning numerical simulation of the exciton energy profile, the electrical field distribution in the system is first calculated using Comsol Multiphysics simulation software. All calculations were performed considering the dimensions of the device as follows: the graphene top gates are around 1.1 μm-wide and spaced ˜0.8 μm apart. The heterostructure is encapsulated between two hBN crystals (˜10 nm on the top and −20 nm at the bottom), and the substrate is heavily doped Si with 270 nm of SiO₂ on top (see FIG. 19a). FIG. 19b shows an example of electrical field in the system in the confinement configuration, with −10 V applied to the central gate and side gates grounded. Interlayer excitons have a built-in out-of-plane dipole moment directed upwards, with an absolute value p=ed=e·7.5 10⁻¹⁰ m, where e is the elementary charge and d=7.5 Å is the layer separation in our heterostructure. They thus experience an energy shift of δE_{ILE}=−pE_{z} in the presence of a vertical electric field E. The resulting force applied on the exciton in the longitudinal direction is proportional to the first derivative of the vertical electric field E_{z} with respect to the channel x axis,

$${F}_{x} = - \frac{\partial {E}_{I L E}}{\partial x} = p \frac{\partial {E}_{z}}{\partial x} .$$

Example profiles of the confinement well configuration are shown in FIG. 19c.

In another embodiment of the present disclosure, the excitonic device 101 defines a polarization switch or device having tunable emission intensity and wavelength. Compared to the previous described excitonic device 101, this excitonic device 101 includes a first two-dimensional material or layer 103 and a second two-dimensional material or layer 105 aligned with respect to each other to minimize the stacking angle (δθ≤1° or ≤1°), and to create a long-period moiré superlattice at the interface.

A small lattice mismatch between the two layers 103, 105 can in the absence of stacking angle result in the creation of a long-period moiré superlattice, with the periodicity larger than the Bohr radius of excitons, thereby influencing their motion.

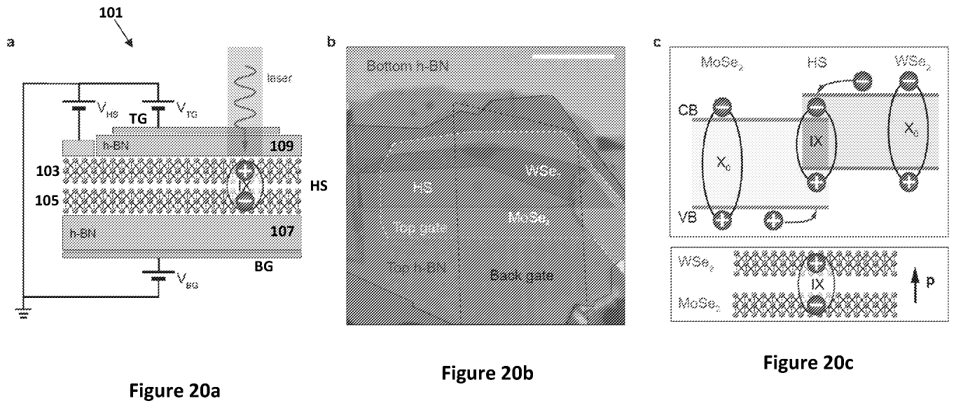

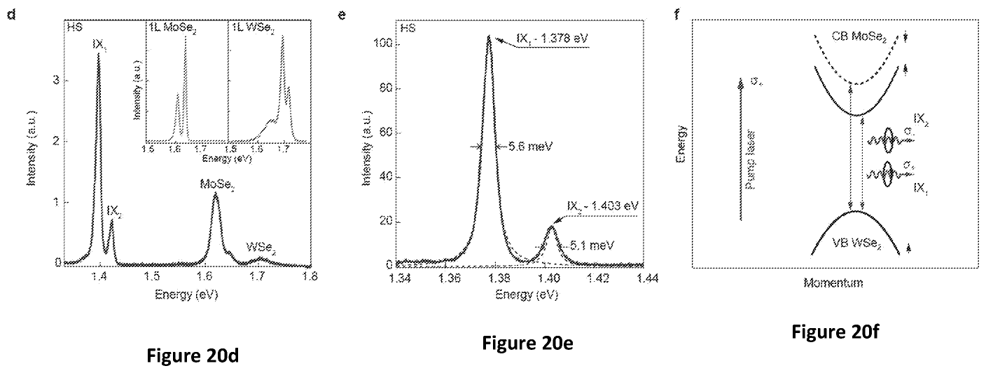

An exemplary device structure is shown in FIG. 20a. A contacted MoSe₂/WSe₂ heterobilayer HS is encapsulated in h-BN, with a graphene bottom gate and a top transparent Pt gate. This stack or structure is realized using the dry-transfer technique on for example a doped silicon substrate covered with 270 nm of SiO₂. The crystals are aligned to minimize the stacking angle (δθ≤1°), thus creating a long-period moiré superlattice.

Few-layer graphene flakes for the bottom gate BG were obtained by exfoliation from graphite (NGS) on Si/SiO₂ substrates and patterned in the desired shape by e-beam lithography and oxygen plasma etching. The heterostructure HS was then fabricated using polymer-assisted transfer³³ of mono- and few-layer flakes of h-BN, WSe₂ and MoSe₂ (HQ Graphene). Flakes were first exfoliated on a polymer double layer. Once monolayers were optically identified, the bottom layer was dissolved with a solvent and free-floating films with flakes were obtained. These were transferred using a setup with micromanipulators to carefully align flakes on top of each other and minimize the stacking angle. For this, a homemade software was used to measure the angle between the flake edges, with a precision limited by the resolution of optical images (<1°). Polymer residue was removed with a hot acetone bath. Once completed, the stack or structure was thermally annealed under high vacuum conditions at 10⁻⁶ mbar for 6 h. Finally, electrical contacts were fabricated using e-beam lithography and metallization (80 nm Pd for contacts, 8 nm Pt for the top-gate).

This excitonic device architecture allows to perform optical measurements while applying different voltages through the top and bottom gates, as well as the global Si back-gate and gives the possibility to independently control the doping level and the transverse electric field. FIG. 20b shows an optical microscopy image of a completed device. The measurements reported herein in relation to this device were acquired at 4.2 K.

All optical measurements presented were performed in vacuum at a temperature of 4.2 K. Excitons were optically pumped by a continuous wave (CW) 647 nm laser diode focused to the diffraction limit with a beam size of about 1 μm. The incident power was ˜200 μW. Spectral and spatial characteristics of the device emission were analysed simultaneously. The emitted light was acquired using a spectrometer (Andor Shamrock with Andor Newton CCD camera), and the laser line was removed with a long pass 650 nm edge filter. For spatial imaging, we used a long-pass 850 nm edge filter so that the laser light and most of the emission from monolayers were blocked. Filtered light was acquired by a CCD camera (Andor Ixon). For polarization-resolved measurements, a lambda-quarter plate on a rotator together with a linear polarizer were used to select the polarization of incident light. A similar setup was used to image the two polarizations on the CCD camera.

The h-BN-encapsulation of the heterostructure allows one to observe bright and sharp photoluminescence (PL) peaks from individual monolayers (FIG. 20d, insets), with full-width half maxima (FWHM) between 7 and 15 meV. In the heterobilayer region HS, an extreme quenching of the intralayer excitonic peaks is observed, together with the appearance of low-energy emission (FIG. 20d) around 1.39 eV due to interlayer exciton (IX) formation. Two distinct emission peaks (FIG. 1e) are clearly resolved, with FWHM around 5 meV and an energy separation of ˜25 meV between them, which corresponds to the MoSe₂ conduction band (CB) spin-splitting. Such high resolution is achieved as a result of improved heterostructure quality. These lower- and higher-energy features are referred to as IX₁ and IX₂ respectively. This doublet is attributed to a spin-conserving and a spin-flipping transition (FIG. 20f). The latter is normally dark (forbidden) in monolayers, but is brightened by the moiré pattern in the heterobilayer HS of the excitonic device 101 of this embodiment due to selection rules dictated by local atomic registry.

Prior to manipulating the polarization of these two transitions, characterization of this excitonic device demonstrates intensity and energy manipulation which enable polarization switching. As previously explained, the excitonic device 101 includes a van der Waals heterostructure with a type-II band alignment (FIG. 20c). Since electrons and holes are confined to separate layers, interlayer excitons have a defined dipole moment \vec{p} perpendicular to the heterostructure plane. This allows to linearly tune their energy with an external electric field \vec{E} along the dipole axis: ΔU˜−\vec{p}·\vec{E}. To this end, the Inventors applied a vertical field at constant carrier concentration. A modulation of the IX emission maximum of ΔU˜138 meV is obtained, from 1.34 to 1.47 eV. A linear fit of the energy shift yields a tuning rate of ˜500 meV·nm·V⁻¹, from which one obtains a qualitative estimation of the dipole size d˜ΔU/qE˜0.5 nm (where q is the elementary charge), compatible with the expected interlayer spacing. While this semiclassical dipole picture is oversimplified, it captures the main effects observed. For positive electric fields, the decrease in energy of the dipole (charges are more separated) results in reduced recombination rate and a slightly larger Stark effect. On the contrary, when the exciton energy is increased, and the overlap between the electron and the hole is larger, brighter PL is observed.

If one grounds the heterobilayer HS while applying voltage to the top gate TG, one can achieve control over the relative intensities of the two peaks by changing the charge carrier concentration. The dual-gated configuration allows to independently control exciton energy or relative peak intensity, while keeping the other property fixed. This geometry also allows for precise control over the doping of individual layers within the heterobilayer. For negative values of V_{TG}, the intensity of the IX₂ peak is first reduced, then suppressed around −4 V. At the same time, IX′ becomes broader and starts to dominate the spectrum. On the contrary, at high positive voltages, one observes that IX₂ becomes the dominant emission feature, while IX₁ decreases in intensity and becomes quenched at higher electron density achieved by dual gating. This resembles closely what one would expect from a two-level system, where with increased doping more electrons are driven into the upper level: here this comes from the filling of the lower spin-split CB and population of the upper one. This interpretation is also supported by the observation of a faster increase in the intensity of IX₂ with increasing laser power in the absence of electrostatic doping. Further confirmation of this filling mechanism is the temperature dependence of the two transitions, with IX₂ becoming stronger as the upper band is thermally populated.

The excitonic device 101 of the present embodiment defines an excitonic valleytronic device.

Valleytronics is an appealing alternative to conventional charge-based electronics and aims at encoding data in the valley degree of freedom, i.e. the information over which extreme of the conduction or valence band carriers are occupying. The ability to create and control valley-currents in solid state devices could therefore enable new paradigms for information processing.

The excitonic device 101 of the present embodiment comprises an optical input and optical output, and information is encoded in the polarization of the light. The valley degree of freedom of the excitons is selectively addressed with polarized light. To this end, characterization of the polarization-resolved photoluminescence from the heterostructure HS is carried out. The emission intensity for positive (σ⁺) and negative (σ⁻) helicity are the same in the case of linear excitation. The situation changes with circularly polarized excitation. One observes robust conservation of the incident polarization from monolayer WSe₂, but not from MoSe₂. The clean interfaces in the encapsulated heterostructures allow to resolve the two different optical transitions, IX₁ and IX₂. One observes that IX₁ and IX₂ have opposite behaviour under circularly polarized excitation, with polarization values up to 27% and −25% respectively. Such behaviour agrees with what is expected from a spin-conserving (-flipping) transition between the WSe₂ valence band (VB) maximum and the lower (upper) CB minimum of MoSe₂. In WSe₂/MoSe₂ both these transitions are allowed, with opposite polarizations and comparable intensities, for excitons localized in some energy minima of the moiré pattern.

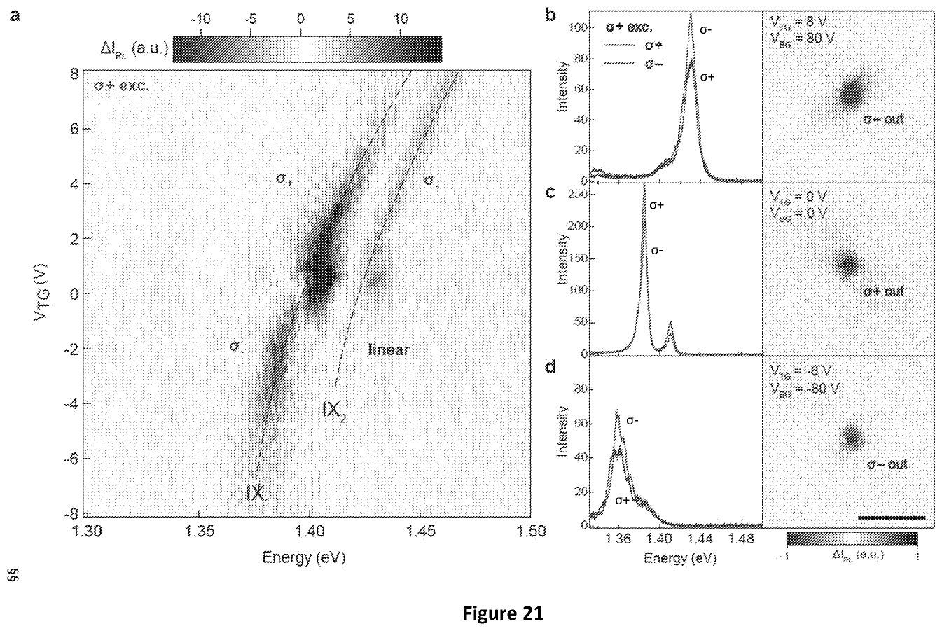

Gate modulation of the two excitonic peaks is combined with their unique polarization dependence. Strong electron doping enhances IX₂, while at small or negative gate voltages IX′ dominates. Thanks to the opposite polarization of the two peaks, this allows to change the device operation between a polarization-inverting and polarization-preserving regime. The corresponding results are shown in FIG. 21: both excitonic peaks are clearly visible in the upper (positive) half of the map, with opposite helicity. In FIG. 21c (left), the spectra corresponding to V_{TG}=0 V is presented. Due to the higher intensity of IX₁ peak, the total polarization of the signal ΔI_{RL} (net polarization ΔI_{RL}=I_{R}−I_{L} integrated over the frequency spectrum) is positive (i.e., of the same sign as the excitation). This is even more clearly visible in the right panel of FIG. 21c, where the spatial image of the exciton polarization acquired on the CCD is shown. For strong electron doping the situation is reversed, as seen on FIG. 21b. In this configuration, IX₂ emission is stronger, resulting in an overall negative value of ΔI_{RL}, and the device 101 operates here as a polarization inverter. Even more interesting is the behaviour in the p-doped region (i.e. for the application of negative gate voltage). The higher energy IX₂ peak is suppressed at negative gate voltages, so one would expect the device to strongly preserve the helicity when electrostatically p-doped. On the contrary, IX₁ polarization behaviour is now completely reversed, while IX₂ shows a vanishing circular polarization (see lower half of FIG. 21a). This results from the alteration of the moiré potential induced by electrostatic doping, which shifts the exciton localization from one to another type of local minima in the moiré pattern, with different local symmetry and thus different light coupling rules. In FIG. 21d the spectra recorded for a strong hole-doped case is shown, demonstrating that the polarization-inverting emission is indeed coming from the lower-energy IX₁. Just as in the case of positive gate voltage, one obtains a globally negative polarization (right panel).

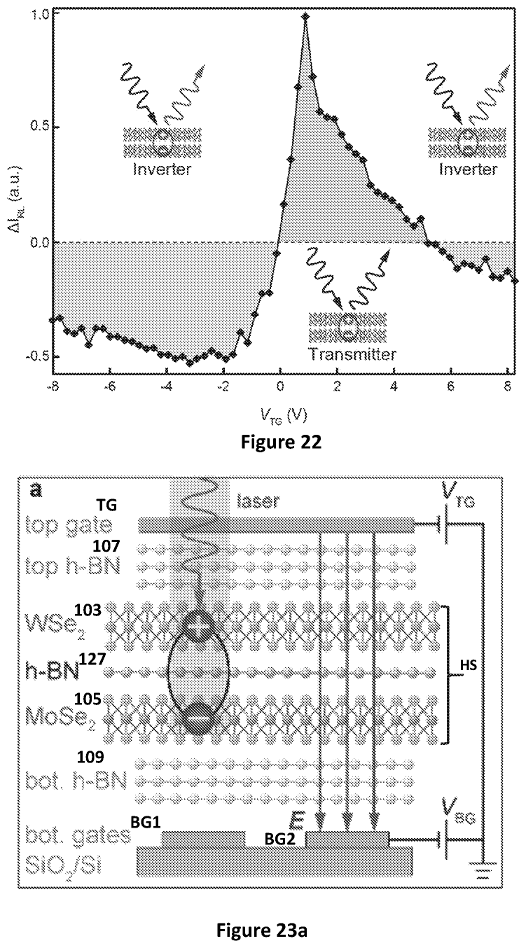

To characterize the switching operation in more detail, the evolution of ΔI_{RL} (polarization integrated over the spectrum) as a function of the applied gate voltage is assessed, as shown in FIG. 22. For a top gate voltage V_{TG} higher than 5 V, one obtains negative ΔI_{RL}, as a result of IX₂ being the strongest transition (as in FIG. 21a). For gate values between 5 V and 0 V, IX₁ dominates, giving positive ΔI_{RL}, i.e. preserving the input polarization. Within this region, application of gate voltage also allows to modulate the amplitude of the effect, with a maximum around V_{TG}=1 V. One then sees a sharp transition between the two logic states happening around zero gate voltage, with a small required switching voltage around ±1 V. This threshold value depends on the gate capacitance, and could thus be considerably reduced by engineering thinner dielectric layers to obtain even higher efficiency. For V_{TG} below 0 V, one has an inverting action, due to the polarization reversal of IX₁.

The excitonic device 101 of this embodiment provides comprehensive electrical control over the polarization, wavelength and intensity of emission from interlayer excitons. The ability to integrate all these functions in a single device to fine-tune the emitted radiation is a key advantage in practical optoelectronics and can pave the way for novel applications for valleytronic devices.

Advantageously, polarization conservation or reversal is gate-tunable, enabling a polarization-inverting action.

The excitonic device 101 enables the manipulation of the electrical manipulation of the polarization of light.

Measurements from this above described excitonic device 101 defining a polarization switch of the present embodiment have been carried out a low temperature to facilitate the understanding of the functioning of the device. This device however can operate at higher temperatures, for example, at a temperature ≤100K.

As described above, a polarization switching method of the present embodiment includes providing the above described excitonic device 101 defining a polarization switch of the present embodiment and pumping the excitonic device with circularly polarized light to generate interlayer excitons.

a first voltage is applied to generate a first electric field across the heterostructure HS to set a first logic state. Additionally or alternatively, a second voltage can be applied to generate a second electric field across the heterostructure HS to set a second logic state.

As explained above, each of the first and second logic states can be determined by measuring the difference ΔI_{RL}=I_{R}−I_{L} between right and left circularly polarized emission intensities emitted by the interlayer excitons when the excitonic device is pumped with circularly polarized light. The right and left circularly polarized emission intensities are obtained by integrating over the measured interlayer exciton emission spectrum.

Transition metal dichalcogenides (TMDCs) are for example a promising platform for valleytronics, due to the presence of two inequivalent valleys with spin-valley locking and a direct band gap, which allows optical initialization and readout of the valley-state. The control of interlayer excitons in these materials offers an effective way to realize optoelectronic devices based on the valley degree of freedom. In accordance with a further embodiment of the present disclosure, the Inventors provide an excitonic device permitting the generation and transport over mesoscopic distances of valley-polarised excitons.

Engineering of the interlayer coupling results in enhanced diffusion of valley-polarised excitons, which can be controlled and switched electrically. Furthermore, using electrostatic traps, one can increase exciton concentration by an order of magnitude, reaching densities in the order of 10¹² cm⁻², opening the route to achieving a coherent quantum state of valley-polarized excitons via Bose-Einstein condensation.

Similar to the previous embodiment, the excitonic device 101 of the present embodiment includes first and second two-dimensional materials or layers 103, 105 whose alignment with respect to each other defines or results in the presence of a moiré superlattice, whether this be intentionally or not.

Heterostructures HS of transition metal dichalcogenides, such as MoSe₂ and WSe₂, can host interlayer excitons, bound electron-hole pairs where charges are spatially separated in opposite layers. These quasi-particles have long lifetimes which can reach hundreds of nanoseconds in very high-quality devices. The spatial separation of different carriers gives interlayer excitons a permanent out-of-plane electrical dipole moment, which can be harnessed in exitonic devices, enabling electrical control of exciton properties and transport up to room temperature due to the strong binding energies in these systems. This constitutes a considerable advantage over previous excitonic devices based on bulk III-V semiconductor heterostructures, whose operation was limited to cryogenic temperatures. Moreover, the valley-dependent optical selection rules in TMDCs permit to selectively populate the K or −K valleys of WSe₂ and MoSe₂ with circularly polarized light, thus creating interlayer excitons with a certain valley-state. This could be used to transport and store information with long lifetimes in interlayer excitons, making them an attractive medium for generating and manipulating valley-polarized currents in solid state devices.

Further possibilities are enabled by the slight lattice mismatch and relative rotation between the two layers, leading to the formation of moiré patterns. The resulting periodic potential and locally-changing optical selection rules allow to obtain highly versatile emitters with electrically tunable energy, intensity and polarisation. However, since the moiré potential can be as high as ˜150 meV, it can effectively trap interlayer excitons in its local minimal¹⁷⁻¹⁹, suppressing their diffusion and impeding the controlled transport of valley-polarized carriers over sizeable distances.

The present embodiment addresses these issues by introducing at least one insulating inter-layer or insulating inter-material 127 located between the first two-dimensional material or layer 103 and the second two-dimensional material or layer 105. The least one insulating inter-layer or insulating inter-material is in direct contact with both the first two-dimensional material or layer 103 and the second two-dimensional material or layer 105. For example, the at least one insulating inter-layer or insulating inter-material comprises or consist solely of boron nitride or hexagonal boron nitride.

The introduction of such an atomically thin spacer between the constituent layers or monolayers of the heterostructure HS permits to further separate the electron- and hole-hosting layers 103, 105. This tuning of interlayer interaction alters the long-range moiré pattern, while preserving the coupling necessary for hosting interlayer excitons. This advantageously allows the realization of an excitonic valley transistor or device in which one can electrically control the transport of excitons carrying a certain valley state.

Alternatively or additionally, by using a confining electrostatic potential one can collect excitons and increase their concentration, with a view towards the creation of a valley-polarised exciton superfluid via Bose-Einstein condensation.

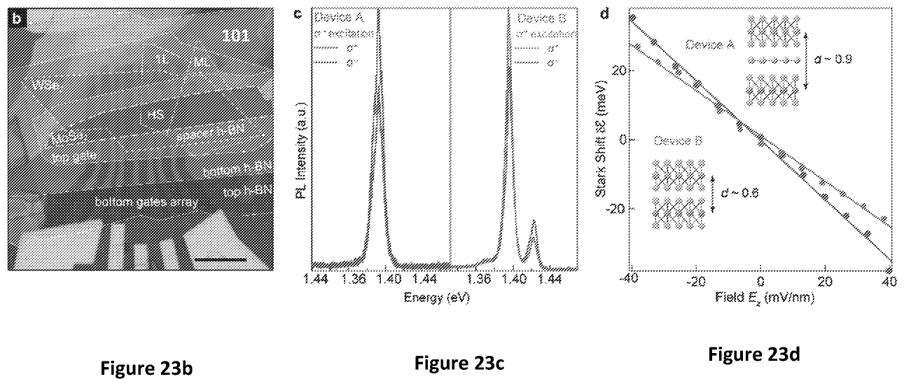

Exemplary heterostructures HS based on MoSe₂ and WSe₂ monolayers 103, 105 were prepared, both with and without the atomically thin hexagonal boron nitride (h-BN) separator 127. FIG. 23a shows a schematic depiction of a tri-layer stack 103, 127, 105 (device A), fully encapsulated by thick h-BN flakes 107, 109 which serve as a flat and clean dielectric environment between the heterostructure and the top- and bottom-gates TG, BG.

In the exemplary heterostructure HS fabrication, thin Cr/Pt (⅔ nm) bottom gates where realized by e-beam lithography and metal evaporation on silicon substrates covered by 270 nm of SiO₂. The heterostructure HS was then fabricated using polymer-assisted transfer of mono- and few-layer flakes of h-BN, WSe₂ and MoSe₂ (HQ Graphene). Flakes were first exfoliated on a polymer double layer. Once monolayers were optically identified and confirmed by photoluminescence, the bottom layer was dissolved with a solvent and free-floating films with flakes were obtained. These were transferred using a setup with micromanipulators to carefully align flakes on top of each other. Polymer residue was removed with a hot acetone bath. Once completed, the stack was thermally annealed under high vacuum conditions at 10⁻⁶ mbar for 6 h. Finally, electrical contacts were fabricated using e-beam lithography and metallization (80 nm Pd for contacts, 8 nm Pt for the top-gate).

Multiple transparent gate electrodes TG, BG allow one to apply laterally-changing vertical electrical fields while performing optical measurements.

All optical measurements were performed in vacuum at 4 K, unless stated otherwise (up to 300 K for temperature dependent measurements), in a He-flow cryostat with optical access. Interlayer excitons were optically pumped with a continuous wave 647-nm diode laser focused to the diffraction limit (spot width of 0.6 μm). For resonant excitation a supercontinuum laser (Fianium) at 720 nm was employed. In order to access a specific valley, a polarizer and a quarter wave (λ/4) plate were used for generating right/left circularly- or linearly-polarized light. For μPL measurements, the emitted light was filtered by a 650-nm long-pass edge filter and then acquired using a spectrometer (Andor Shamrock with a charge-coupled device (CCD)). Polarization-resolved μPL measurements were performed by employing another λ/4 plate and a birefringent Yttrium Orthovanadate beam displacer, so that σ⁺ and σ⁻ signals could be acquired on the spectrometer simultaneously.

Spatial imagining of the interlayer exciton emission was captured by a CCD camera (Andor Ixon) with an 850-nm long-pass edge filter that removes both the laser line and the intralayer emission from MoSe₂ and WSe₂. A similar setup with a λ/4 plate on a rotator and a fixed linear polarizer was exploited for polarization-resolved PL imaging. Finally, the spectrally-resolved PL images were acquired by the following scheme: the light from the heterostructure HS was transmitted through a Dove prism, an 800-nm long-pass edge filter and a slit, and then was projected on the diffraction grating of the spectrometer. The Dove prism was positioned in such a way that the longitudinal axis of the gate (y-axis) was perpendicular to both the spectrometer slit and the lines of the diffraction grating. This way, spectral cut-lines along x-axis of the device were projected on the CCD camera of the spectrometer.

FIG. 23b shows a microscopy image of device A including the tri-layer stack 103, 127, 105. A second device 101 comprising a heterostructure HS without h-BN spacer 127 (denoted as device B) was also characterized to directly highlight the effect of the interposed layer 127.

Polarization-resolved micro-photoluminescence (μPL) spectra was acquired by exciting the device A and device B with a 647 nm-laser at 4 K. Upon photon absorption, the type-II band alignment of MoSe₂ and WSe₂ leads to fast charge separation of photo-generated carriers, followed by the formation of interlayer excitons (IXs) from electrons in MoSe₂ and holes in WSe₂.

For device A, one observes the appearance of a single low-energy interlayer transition at 1.39 eV which preserves the circular polarization of incoming light (FIG. 23c, left panel). This is in sharp contrast to bilayer samples without h-BN spacer 127 like device B, where one observes an interlayer doublet, characteristic of aligned heterobilayers HS, with opposite helicities for the two peaks (FIG. 23c, right panel). For device A, the polarization of the emitted light ρ (measure of valley-state conservation) has comparable magnitude to device B, decays with increasing temperature and is tunable by gate voltage. Furthermore, non-zero polarization is detected at temperatures as high as 150 K, while the interlayer exciton emission can be observed up to room temperature, making these structures promising for applications at elevated temperatures.

Since the interlayer exciton has a built-in out-of-plane dipole moment p, the application of an external electrical field E perpendicular to the structure shifts its energy by Δε=−p·E. This Stark shift is extracted from μPL spectra taken as a function of the applied electric field (FIG. 23d) for both devices A and B. The slope of the energy shift is proportional to the size of the IX dipole d=Δε/eE_{z}, where e is the elementary charge. One obtains d≈0.9 nm for device A, which is considerably larger than what previously reported for bilayer structures and observed in device B (d_{B}≈0.6 nm), with a difference similar to the thickness of a monolayer of h-BN (˜0.3 nm).

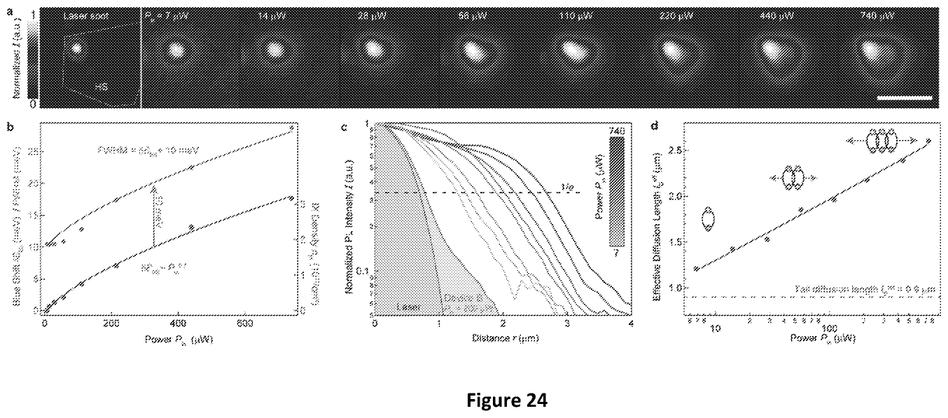

The excitonic device A of the present embodiment permits enhanced diffusion of the interlayer excitons. The diffusion of excitons as a function of incident power is examined. For this, the corner of device A is excited with a diffraction-limited focused laser beam (see FIG. 24a, first panel) while acquiring μPL spectra as well as spatial images of the exciton photoluminescence. As shown in FIG. 24a, when increasing the laser power Pᵢₙ, the size of the exciton cloud grows significantly. With increasing laser power, one sees that the PL emission moves to higher energy and broadens, while the intensity grows linearly. The lack of saturation is interpreted as a signature of reduced exciton-exciton annihilation effects due to the h-BN separator. By monitoring the blue-shift of the emitted light ε_{BS}, one can estimate a lower bound for the exciton density n_{1X}, following a simple parallel plate capacitance model:

$${ɛ}_{BS} = {n}_{IX} \frac{d {e}^{2}}{{ɛ}_{HS} {ɛ}_{0}}$$

where the dipole size d was determined from the Stark shift, ε₀ is the vacuum permittivity and ε_{HS}=6.26 is the effective relative permittivity of the WSe₂/h-BN/MoSe₂ heterotrilayer of device A. As shown in FIG. 24b, the energy shift grows sub-linearly, but does not saturate over the explored range of powers. A maximum carrier density of n_{1X}˜3 ·10¹¹ cm⁻² is extracted that is limited by the excitation power used. For comparison, the maximum density one can achieve for the device B is considerably smaller, below 10¹⁰ cm⁻². This is ascribed to Auger recombination at high pumping power.

After characterizing the exciton density, exciton diffusion is now examined. From CCD images profiles of emission intensity as a function of the distance r from the excitation spot (normalized by their intensity at r=0) are obtained, as illustrated in FIG. 24c. Detailed analysis reveals two distinct diffusion regimes. Closer to the excitation spot, where exciton repulsion is dominant, one observes a very slow decay and large diffusion length (I_{D}>20 μm), while further away the signal declines faster, with a universal slope like the one seen at low power (I_{D}˜0.9 μm). In FIG. 24d we plot the effective exciton diffusion length I_{D}^{eff}, defined as the distance where the emission intensity drops to 1/e of its initial value. This value grows with the excitation power Pᵢₙ, reaching l_{D}^{eff}=2.6 μm at Pᵢₙ=740 μW. For comparison, the profile from device B is shown (shaded line and section FIG. 24c), where one observes a much weaker diffusion. The Inventors attribute this to the effect of moiré pattern and stronger Auger recombination, both of which are expected to be suppressed by the separator 127 of the present embodiment. Therefore, in what follows below, the tri-layer device (device A) is focused on.

The present embodiment thus concerns an excitonic switching method in which interlayer excitons are generated in the least one heterostructure HS of the above described excitonic device 101 (device A).

The generated interlayer excitons can be allowed to displace along the least one heterostructure (HS). Alternatively or additionally, a potential barrier can be created by applying an electric field through the least one heterostructure (HS) to impede or block interlayer exciton displacement. Logic states can thus be defined, for example, a first logic state (for example, device ‘OFF’ state) when the potential barrier is present and a second logic state (for example, device ‘ON’ state) when the potential barrier is removed, and the interlayer excitons displace across the heterostructure (HS).

A voltage is applied to generate an electric field across the heterostructure HS to set a first logic state; and the voltage is removed to set a second logic state.

Advantageously, the excitonic device 101 of the present embodiment can define or be used as a valley excitonic transistor. Long diffusion length at high incident power allows to realize an electrically-operated excitonic switch device.

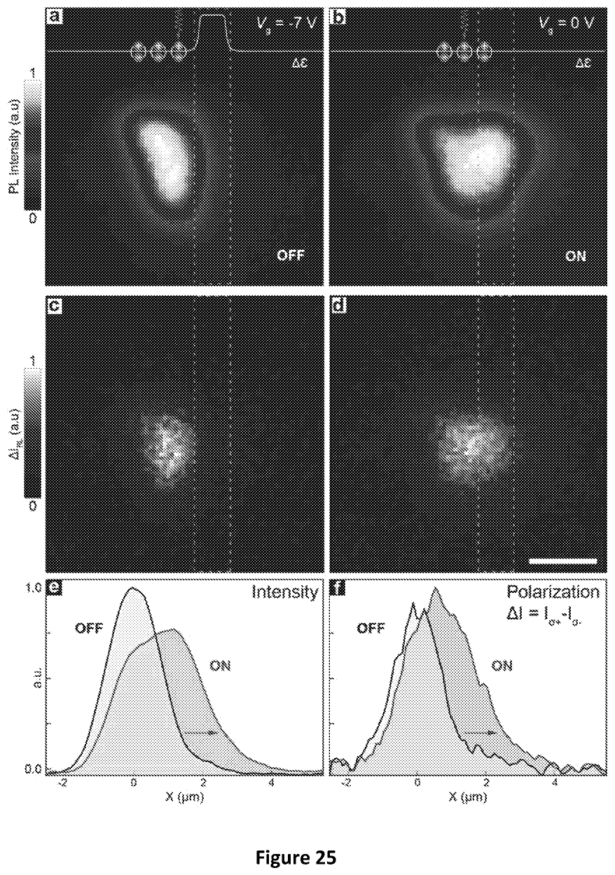

By using the multiple back-gates, one creates a laterally-modulated electric field along an x direction, which in turn produces a spatial variation of the energy profile Δε(x) for the excitons. Interlayer excitons IXs can be excited by parking the laser spot (Pᵢₙ=500 μW) in the corner of the heterostructure HS, for example on the left side of a narrow back-gate BG (see FIG. 25). By making the gate area higher or lower in energy with respect to its surroundings, one can allow or block the exciton diffusion. FIGS. 25a and 25b illustrate the spatial extent of the PL emission, i.e. the shape of the exciton cloud, for the two cases. In the top part of the images (overlay) the calculated interlayer exciton energy modulation Δε(x)=−p·E(x) is shown as a function of the lateral position x for the configurations, together with a schematic depiction of the expected exciton motion. For V_{g}=−7 V the gated area acts as energy barrier, effectively blocking the excitons at its edge (OFF-state), as shown in FIG. 25a. For V_{g}=0 V instead excitons are free to diffuse in a flat potential and move along the “channel” (ON-state), while their emission intensity decays over distance, as in FIG. 25b. A ˜1.4 μm difference in exciton diffusion is observed when comparing ON and OFF states (see FIG. 25e).

To gain further insight into drift/diffusion process, the Inventors also probe the exciton energy spectra as a function of the spatial coordinate while operating the excitonic transistor device where diffusion of exciton into the lower-energy region is clearly seen.

Combining the excitonic device operation with valley preservation, one can realize a valley switch, effectively controlling the flow of valley-polarized excitons. For this, the Inventors optically initialize the exciton valley-state by exciting the excitonic device with σ+ circularly-polarized light.

The result is displayed in FIGS. 25c to 25d, where spatial images of the emitted polarization ΔI=I_{σ}+ are shown for the OFF and ON states. By analysing the decay of ΔI with distance in FIG. 25f, ones see that valley-polarized excitons can either be stopped before the control gate, or travel over an additional ˜1.3 μm-distance when in the ON-state.

While here one is interested particularly in demonstrating a proof of concept, the Inventors nevertheless notice that the initial degree of polarization (here ˜15%) could be further improved by resonant excitation. It is also noticed that the measured polarization is slightly higher in the ON state, that is assigned to an additional repulsion of majority excitons due to the exchange coulomb interaction. As mentioned earlier, the large binding energy allows one to observe interlayer excitons IXs at high temperatures. Indeed, it is possible can operate this valley-switch up to a temperature of 100 K (can operate at a temperature ≤100K), and the simple excitonic switch at temperatures as high as 150 K (can operate at a temperature ≤150K).

The present embodiment thus concerns another excitonic switching method in which valley-polarized interlayer excitons are generated in the least one heterostructure HS of the above described excitonic device 101 (device A) by, for example, exciting the at least one heterostructure HS with σ+ circularly-polarized light to generate valley-polarized excitons.

The generated valley-polarized excitons can be allowed to displace along the least one heterostructure HS. Alternatively or additionally, a potential barrier can be created by applying an electric field through the least one heterostructure HS to impede or block valley-polarized exciton displacement. Logic states can thus be defined, for example, a first logic state (for example, device ‘OFF’ state) when the potential barrier is present and a second logic state (for example, device ‘ON’ state) when the potential barrier is removed, and the interlayer excitons displace across the heterostructure (HS).

The first (OFF) and second (ON) logic states are determined by measuring an emitted polarization difference (ΔI=I_{σ}_{⁺}−I_{σ}_{^{−}}) between right and left circularly polarized emission intensities emitted by the valley-polarized excitons when the excitonic device is pumped with circularly polarized light. The right and left circularly polarized emission intensities are obtained by integrating over the measured interlayer exciton emission spectrum.

A voltage is applied to generate an electric field across the heterostructure HS to set a first logic state; and the voltage is removed to set a second logic state.

The excitonic device of the present embodiment can also be used or define an excitonic trap because one can use the same principle not only to control fluxes of valley-polarized excitons, but also to confine them to achieve higher densities. Indeed, while the emission intensity rises linearly with pumping power, the blueshift increases sub-linearly (FIG. 24b) due to exciton-exciton repulsion lowering the density. To counteract this, the Inventors generate an electrostatically-defined potential well to constrain the valley-polarized excitons and concentrate them further.

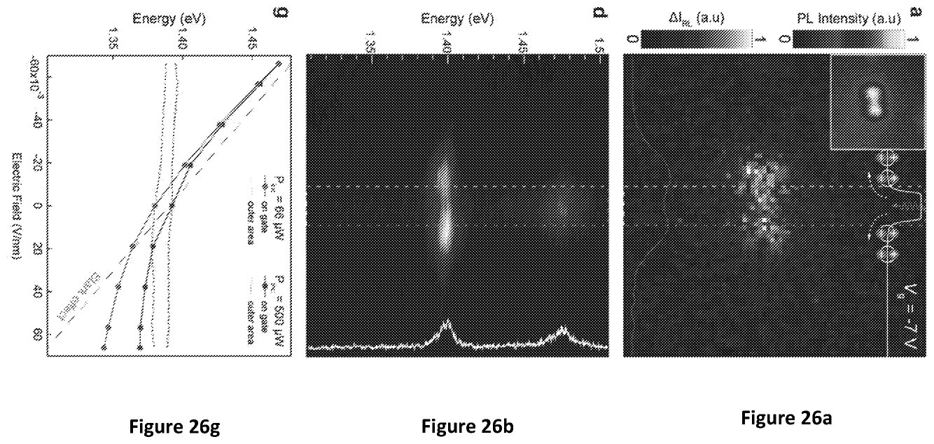

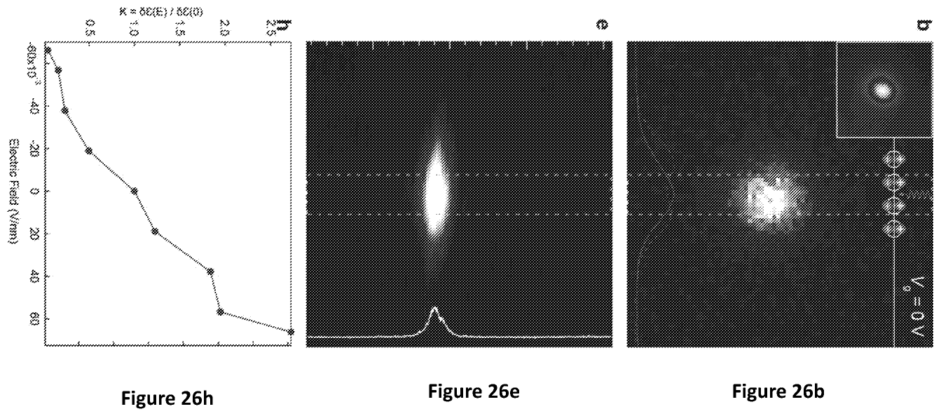

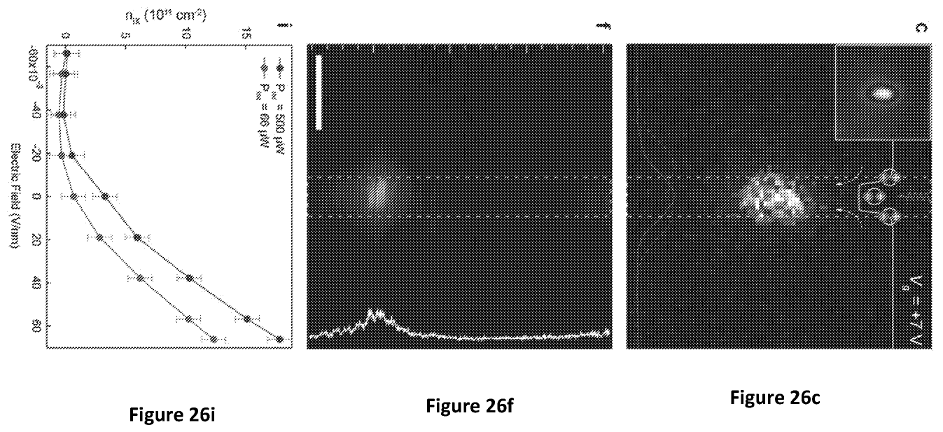

A circularly-polarized laser (720 nm) directly on the area where an electric field is applied. As displayed in FIG. 26a, anti-confining splits the valley-polarized exciton cloud in two lobes, pushing excitons away from the generation point. On the contrary, when we create a potential well in the lateral direction (FIG. 26c), excitons are squeezed to a narrower area compared to its natural diffusion (FIG. 26b).

Looking at the exciton energy as a function of position one can get more information. In the barrier case (FIG. 26d) excitons are separated in two regions spatially and energetically: excitons generated in the gate area (indicated by dashed lines in FIG. 26) have higher energy, hence they diffuse to the sides, where they emit light at the same energy of the zero-field case (FIG. 26e). This is consistent with the strongest PL emission being localized on the two sides of the barrier, and not at the laser spot. On the other hand, when we create a potential well, exciton energy is lowered, producing spatial confinement (FIG. 260. Interestingly, the energy shift of excitons is not symmetric with respect to the applied field (as expected from pure Stark-effect).

In FIG. 26g, the energy of excitons in the region inside (solid) and outside (dotted) of the gate area is plotted as a function of electric field for two different excitations. At zero electric field, increasing the incident power generates a relative blueshift about ˜12 meV, in agreement with FIG. 24b. However, when one disperses the excitons (negative field), this blueshift is cancelled. Even more strikingly, when one starts to confine the excitons, two phenomena appear: first, the magnitude of the blueshift between low- and high-power increases; and second, the exciton energy deviates drastically from a linear behaviour, especially in the high-power case. The Inventors attribute this non-linearity to the changing density inside the trap: since excitons are confined, their average energy is not only shifted by Stark effect, but also has a strong contribution from exciton-exciton interaction depending on local density: Δε=−p·E+n_{IX}de²/ε_{HS}ε₀. Conversely, when one separates them, even at higher power the density is low enough to make interactions negligible. The Inventors quantify the resulting modulation of exciton density by two methods. First, they look at how the blueshift Δε(E)=ε_{500 μW}(E)−ε_{66 μW}(E) is enhanced by the applied field E

$$K ( E ) = \frac{Δɛ ( E )}{Δɛ ( 0 )} .$$

This quantifies the increase in exciton density Δn_{IX} induced by higher power (see FIG. 26h) as a function of E, indicating that electrostatic confinement can modulate the exciton density. However, one is mostly interested in estimating the actual exciton density in the trap. For this, the Inventors isolate the non-linear contribution to Δε(E), proportional to the exciton density, by removing the Stark effect (dashed line in FIG. 26g). The result is shown in FIG. 26i, which allows to put a lower bound on the concentration of polarized excitons at n_{IX}˜1.8×10¹² cm⁻², promising for the production of a degenerate Bose gas.

Indeed, the control over the concentration of polarized excitons represents a significant step towards the realization of high-temperature Bose-Einstein condensates of valley-excitons in these excitonic devices. Including a potential profile such as ramp profile or including an optimized trap in the excitonic device should permit to achieve even higher exciton concentrations in thermal equilibrium, enabling the collection of thermalized excitons produced by pulsed excitation at even higher densities.

The present embodiment thus provides an excitonic device operating method for confining or trapping an valley-polarized exciton cloud. Valley-polarized excitons are generated in a generation zone GZ of the heterostructure HS by exciting the at least one heterostructure HS with σ+ circularly-polarized light.

A potential well is created at or in the vicinity of the generation zone GZ by applying an electric field at the generation zone GZ. This permits to achieve electrical confinement of the valley-polarized interlayer excitons. Alternatively or additionally, a repulsive barrier can be created at the generation zone GZ by applying an electric field in an opposite direction at to expulse the valley-polarized interlayer excitons from the generation zone GZ.

The created potential well confines the valley-polarized interlayer excitons to form a bound valley-polarized interlayer exciton cloud. Removal of the created potential well allows displacement of the exciton cloud.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims. The features of any one of the above described embodiments may be included in any other embodiment described herein.

### REFERENCES

1. High, A. A., Hammack, A. T., Butov, L. V., Hanson, M. & Gossard, A. C. Exciton optoelectronic transistor. Opt. Lett. 32, 2466-2468 (2007).
2. High, A. A., Novitskaya, E. E., Butov, L. V., Hanson, M. & Gossard, A. C. Control of Exciton Fluxes in an Excitonic Integrated Circuit. Science 321, 229-231 (2008).
3. Grosso, G. et al. Excitonic switches operating at around 100 K. Nat. Photonics 3, 577-580 (2009).
4. Cheiwchanchamnangij, T. & Lambrecht, W. R. L. Quasiparticle band structure calculation of monolayer, bilayer, and bulk MoS₂. Phys. Rev. B 85, 205302 (2012).
5. He, K. et al. Tightly Bound Excitons in Monolayer WSe₂. Phys. Rev. Lett. 113, 026803 (2014).
6. Rivera, P. et al. Observation of long-lived interlayer excitons in monolayer MoSe₂—WSe₂ heterostructures. Nat. Commun. 6, 6242 (2015).
7. Palummo, M., Bernardi, M. & Grossman, J. C. Exciton Radiative Lifetimes in Two-Dimensional Transition Metal Dichalcogenides. Nano Lett. 15, 2794-2800 (2015).
8. Miller, B. et al. Long-Lived Direct and Indirect Interlayer Excitons in van der Waals Heterostructures. Nano Lett. 17, 5229-5237 (2017).
9. Žutić, I., Fabian, J. & Das Sarma, S. Spintronics: Fundamentals and applications. Rev. Mod. Phys. 76, 323-410 (2004).
10. Miller, D. A. B. Rationale and challenges for optical interconnects to electronic chips. Proc. IEEE 88, 728-749 (2000).
11. Butov, L. V. Excitonic devices. Superlattices Microstruct. 108, 2-26 (2017).
12. Liu, A. et al. A high-speed silicon optical modulator based on a metal-oxide-semiconductor capacitor. Nature 427, 615 (2004).
13. Melikyan, A. et al. High-speed plasmonic phase modulators. Nat. Photonics 8, 229 (2014).
14. Xu, Q., Schmidt, B., Pradhan, S. & Lipson, M. Micrometre-scale silicon electro-optic modulator. Nature 435, 325 (2005).
15. Schmidt, B., Xu, Q., Shakya, J., Manipatruni, S. & Lipson, M. Compact electro-optic modulator on silicon-on-insulator substrates using cavities with ultra-small modal volumes. Opt. Express 15, 3140-3148 (2007).
16. Fedichkin, F. et al. Room-Temperature Transport of Indirect Excitons in AlGaN/GaN Quantum Wells. Phys. Rev. Appl. 6, 014011 (2016).
17. Kuznetsova, Y. Y. et al. Transport of indirect excitons in ZnO quantum wells. Opt. Lett. 40, 3667-3670 (2015).
18. Fogler, M. M., Butov, L. V. & Novoselov, K. S. High-temperature superfluidity with indirect excitons in van der Waals heterostructures. Nat. Commun. 5, 4555 (2014).
19. Robert, C. et al. Exciton radiative lifetime in transition metal dichalcogenide monolayers. Phys. Rev. B 93, 205423 (2016).
20. Kang, J., Tongay, S., Zhou, J., Li, J. & Wu, J. Band offsets and heterostructures of two-dimensional semiconductors. Appl. Phys. Lett. 102, 012111 (2013).
21. Chen, C.-H. et al. Determination of band alignment in the single-layer MoS₂/WSe₂ heterojunction. Nat. Commun. 6, 7666 (2015).
22. Fang, H. et al. Strong interlayer coupling in van der Waals heterostructures built from single-layer chalcogenides. Proc. Natl. Acad. Sci. 111, 6198-6202 (2014).
23. Kunstmann, J. et al. Momentum-space indirect interlayer excitons in transition-metal dichalcogenide van der Waals heterostructures. Nat. Phys. 1 (2018). doi:10.1038/s41567-018-0123-y
24. Kim, J. et al. Observation of ultralong valley lifetime in WSe₂/MoS₂ heterostructures. Sci. Adv. 3, e1700518 (2017).
25. Shi, H. et al. Exciton Dynamics in Suspended Monolayer and Few-Layer MoS₂ 2 D Crystals. ACS Nano 7, 1072-1080 (2013).
26. Yan, T., Qiao, X., Liu, X., Tan, P. & Zhang, X. Photoluminescence properties and exciton dynamics in monolayer WSe₂. Appl. Phys. Lett. 105, 101901 (2014).
27. Onga, M., Zhang, Y., Ideue, T. & Iwasa, Y. Exciton Hall effect in monolayer MoS₂. Nat. Mater. advance online publication, (2017).
28. Nagler, P. et al. Interlayer exciton dynamics in a dichalcogenide monolayer heterostructure. 2D Mater. 4, 025112 (2017).
29. Wang, R. et al. Ultrafast and spatially resolved studies of charge carriers in atomically thin molybdenum disulfide. Phys. Rev. B 86, 045406 (2012).
30. Mayorov, A. S. et al. Micrometer-Scale Ballistic Transport in Encapsulated Graphene at Room Temperature. Nano Lett. 11, 2396-2399 (2011).
31. Zhu, H. et al. Interfacial Charge Transfer Circumventing Momentum Mismatch at Two-Dimensional van der Waals Heterojunctions. Nano Lett. 17, 3591-3598 (2017).
32. Schneider, C. A., Eliceiri, K. W. & Rasband, W. S. NIH Image to ImageJ: 25 years of image analysis. Nature Methods (2012). doi:10.1038/nmeth.2089
33. Mayorov, A. S. et al. Micrometer-Scale Ballistic Transport in Encapsulated Graphene at Room Temperature. Nano Lett. 11, 2396-2399 (2011).

The entire contents of each of the above references are herewith incorporated by reference.

1-40. (canceled)

41. Excitonic device including:
at least one heterostructure comprising or consisting solely of a first two-dimensional material or layer and a second two-dimensional material or layer, the at least one heterostructure being configured to generate interlayer excitons at high temperature or room temperature.

42. Excitonic device according to claim 41, further including at least one gate electrode configured to apply an electric field to the at least one heterostructure to control an exciton flux in the at least one heterostructure.

43. Excitonic device according to claim 42, wherein the at least one gate electrode comprises a top gate electrode configured to apply an electric field perpendicular to a crystal plane of the at least one heterostructure.

44. Excitonic device according to claim 41, including a plurality of top gate electrodes configured to apply an electric field to the at least one heterostructure to create a laterally modulated electric field to drive an exciton flux and/or exciton motion towards regions of lower energy.

45. Excitonic device according to claim 42, further including at least one bottom gate electrode.

46. Excitonic device according to claim 42, further including encapsulation layers sandwiching the at least one heterostructure.

47. Excitonic device according to claim 42, further including a substrate to which the least one heterostructure is attached.

48. Excitonic device according to claim 42, wherein the first and second two-dimensional materials or layers comprises or consist solely of a transition metal dichalcogenide.

49. Excitonic device according to claim 42, wherein the first two-dimensional material or layer comprises MoS₂ and the second two-dimensional material or layer comprises WSe₂.

50. Excitonic device according to claim 46, wherein the encapsulation layers comprise or consist solely of boron nitride or hexagonal boron nitride.

51. Excitonic device according to claim 42, further including interlayer exciton generation means configured to generate interlayer excitons in the least one heterostructure.

52. Excitonic device according to claim 41, wherein room temperature is a temperature between 15 and 45° C. these range extremity values included, and high temperature is a temperature between −100° C. and 45° C. these range extremity values included.

53. Excitonic switching method including the steps of:
providing an excitonic device according to claim 41;
generating interlayer excitons in the least one heterostructure;
allowing the generated interlayer excitons to displace along the least one heterostructure; and
creating a potential barrier by applying an electric field through the least one heterostructure to impede or block interlayer exciton displacement.

54. Method according to claim 53, further including removing the potential barrier by reducing or removing the electric field through the least one heterostructure to permit interlayer exciton displacement.

55. Method according to the previous claim 53, further including the step of optically initializing an exciton valley-state by exciting the at least one heterostructure with σ+ circularly-polarized light to generate valley-polarized excitons.

56. Method according to claim 55, wherein first and second logic states are determined by measuring an emitted polarization difference between right and left circularly polarized emission intensities emitted by the interlayer excitons when the excitonic device is pumped with circularly polarized light, the right and left circularly polarized emission intensities being obtained by integrating over the measured interlayer exciton emission spectrum.

57. Method according to claim 53, wherein a voltage is applied to generate an electric field across the heterostructure to set a first logic state; and the voltage is removed to set a second logic state.

58. Excitonic device operating method including the steps of:
providing an excitonic device according to claim 41;
generating interlayer excitons in the least one heterostructure; and
creating one or more potential ladders or a potential gradient for manipulating the interlayer excitons by applying a plurality of different electric fields through the least one heterostructure, the electric fields being applied at different spatial portions across the least one heterostructure to create a drift field in an interlayer exciton displacement direction through the least one heterostructure.

59. Method according to claim 58, wherein the excitonic device includes a plurality of electrodes configured to generate a plurality of spatially separated electric fields through the at least one heterostructure, wherein the spatially separated electric fields are spatially separated along a plane of the excitonic device.

60. Method according to claim 58, wherein the method is an excitonic switching method.
